(19) United States
(12) Patent Application Publication
(10) Pub. No.: US 2019/0346762 A1
(43) Pub. Date: Nov. 14, 2019

(54) CURABLE COMPOSITION, CURED FILM, NEAR INFRARED CUT FILTER, SOLID IMAGE PICKUP ELEMENT, IMAGE DISPLAY DEVICE, AND INFRARED SENSOR

(71) Applicant: FUJIFILM Corporation, Tokyo (JP)

(72) Inventors: Shunsuke KITAJIMA, Haibara-gun (JP); Daisuke SASAKI, Haibara-gun (JP)

(73) Assignee: FUJIFILM Corporation, Tokyo (JP)

(21) Appl. No.: 16/525,168

(22) Filed: Jul. 29, 2019

Related U.S. Application Data
(63) Continuation of application No. PCT/JP2018/001554, filed on Jan. 19, 2018.

(30) Foreign Application Priority Data
Feb. 22, 2017 (JP) 2017-030708

(51) Int. Cl. G03F 7/00; G03F 7/004; G03F 7/031; G03F 7/033; G02B 5/20; G02B 1/04

(52) U.S. Cl. CPC G03F 7/0007; G03F 7/0045; G02B 1/04; G03F 7/033; G02B 5/208; G03F 7/031

(57) ABSTRACT

A curable composition includes: a near infrared absorbing colorant; a polymerizable compound; and a photopolymerization initiator, in which the near infrared absorbing colorant is a compound that includes a π-conjugated plane having a monocyclic or fused aromatic ring, and the photopolymerization initiator does not substantially include a compound having an oxime structure.

### CROSS-REFERENCE TO RELATED APPLICATIONS

This application is a Continuation of PCT International Application No. PCT/JP2018/1554, filed on Jan. 19, 2018, which claims priority under 35 U.S.C. § 119(a) to Japanese Patent Application No. 2017-030708, filed on Feb. 22, 2017. Each of the above application(s) is hereby expressly incorporated by reference, in its entirety, into the present application.

### BACKGROUND OF THE INVENTION

### 1. Field of the Invention

The present invention relates to a curable composition, a cured film, a near infrared cut filter, a solid image pickup element, an image display device, and an infrared sensor.

### 2. Description of the Related Art

In a video camera, a digital still camera, a mobile phone with a camera function, or the like, a charge coupled device (CCD) or a complementary metal-oxide semiconductor (CMOS), which is a solid image pickup element for a color image, is used. In a light receiving section of this solid image pickup element, a silicon photodiode having sensitivity to infrared light is used. Therefore, visibility may be corrected using a near infrared cut filter.

A near infrared cut filter is manufactured, for example, using a curable composition including a near infrared absorbing colorant, a polymerizable compound, and a photopolymerization initiator (refer to WO2015/166873A).

On the other hand, JP1999-295506A (JP-H11-295506A) describes that a near infrared shielding reflection-reducing material can be used in various displays such as a plasma display, the near infrared shielding reflection-reducing material being formed by applying a fluorine-containing polyfunctional (meth)acrylate coating solution to a surface of a near infrared shielding substrate and curing the applied coating solution to form an antireflection layer.

### SUMMARY OF THE INVENTION

In a case where a cured film is formed using a curable composition including a near infrared absorbing colorant, a polymerizable compound, and a photopolymerization initiator, the cured film may be formed using the curable composition immediately after the preparation or may be manufactured using the curable composition that is stored for a long period of time after the preparation.

According to an investigation by the present inventors, it was found that the spectral characteristics of the cured film obtained using the curable composition are likely to vary as the storage time of the curable composition increases. In particular, in a case where a curable composition including a large amount of a near infrared absorbing colorant is used, a variation in spectral characteristics caused by storage is likely to occur.

In particular, WO2015/166873A and JP1999-295506A (JP-H11-295506A) neither describe nor imply a variation in spectral characteristics after the storage of the curable composition.

Accordingly, an object of the present invention is to provide a curable composition having excellent storage stability with which a cured film having a suppressed variation in spectral characteristics even after storage can be formed, a cured film, a near infrared cut filter, a solid image pickup element, an image display device, and an infrared sensor.

Recently, an oxime compound has been widely used as a photopolymerization initiator in a curable composition for forming a cured film because the sensitivity of the obtained cured film is excellent. The present inventors conducted an investigation on a curable composition including a near infrared absorbing colorant, a polymerizable compound, and a photopolymerization initiator, and found that, in a case where an oxime compound is used as a photopolymerization initiator, the spectral characteristics of a cured film obtained using the curable composition after storage are likely to vary. The present inventors conducted a thorough investigation on the reason why the spectral characteristics are likely to vary, and presumed that the formation of an aggregate of the near infrared absorbing colorant is inhibited due to an interaction between a component derived from the oxime compound and the near infrared absorbing colorant during the storage of the curable composition such that the spectral characteristics are likely to vary. Therefore, the present inventors found that, by using a photopolymerization initiator including substantially no oxime compound, a curable composition with which a cured film having a suppressed variation in spectral characteristics even after a long-term storage can be formed can be provided, thereby completing the present invention. The present invention provides the following.

<1> A curable composition comprising:

a near infrared absorbing colorant;

a polymerizable compound; and

a photopolymerization initiator,

in which the near infrared absorbing colorant is a compound that includes a π-conjugated plane having a monocyclic or fused aromatic ring,

a content of the near infrared absorbing colorant is 3 mass % or higher with respect to a total solid content of the curable composition, and

the photopolymerization initiator does not substantially include a compound having an oxime structure.

<2> The curable composition according to <1>,

in which the photopolymerization initiator includes at least one selected from an alkylphenone compound, an acylphosphine oxide compound, a biimidazole compound, or a triazine compound.

<3> The curable composition according to <2>,

in which the photopolymerization initiator includes at least one selected from an alkylphenone compound or an acylphosphine oxide compound.

<4> The curable composition according to any one of <1> to <3>,

in which the near infrared absorbing colorant includes at least one selected from a pyrrolopyrrole compound, a cyanine compound, or a squarylium compound.

<5> The curable composition according to any one of <1> to <3>,

in which the near infrared absorbing colorant includes at least two compounds having different maximum absorption wavelengths.

<6> A cured film which is formed using the curable composition according to any one of <1> to <5>.

<7> A near infrared cut filter comprising:

the cured film according to <6>.

<8> A solid image pickup element comprising:

the cured film according to <6>.

<9> An image display device comprising:

the cured film according to <6>.

<10> An infrared sensor comprising:

the cured film according to <6>.

According to the present invention, it is possible to provide a curable composition having excellent storage stability with which a cured film having a suppressed variation in spectral characteristics even after storage can be formed. In addition, it is also possible to provide a cured film, a near infrared cut filter, a solid image pickup element, an image display device, and an infrared sensor.

### BRIEF DESCRIPTION OF THE DRAWINGS

FIG. 1 is a schematic diagram showing an embodiment of an infrared sensor.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In this specification, “(meth)acrylate” denotes either or both of acrylate or methacrylate, “(meth)acryl” denotes either or both of acryl and methacryl, “(meth)allyl” denotes either or both of allyl and methallyl, and “(meth)acryloyl” denotes either or both of acryloyl and methacryloyl.

In this specification, a weight-average molecular weight and a number-average molecular weight are defined as values in terms of polystyrene obtained by gel permeation chromatography (GPC). In this specification, an weight-average molecular weight (Mw) and a number-average molecular weight (Mn) can be obtained by using HLC-8220 (manufactured by Tosoh Corporation), using TSKgel Super AWM-H (manufactured by Tosoh Corporation; 6.0 mm ID (inner diameter)×15.0 cm) as a column, and using a 10 mmol/L lithium bromide N-methylpyrrolidinone (NMP) solution as an eluent.

In this specification, near infrared light denotes light (electromagnetic wave) having a maximum absorption wavelength in a wavelength range of 700 to 2,500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Curable Composition>

A curable composition according to an embodiment of the present invention comprises: a near infrared absorbing colorant; a polymerizable compound; and a photopolymerization initiator, in which the near infrared absorbing colorant is a compound that includes a π-conjugated plane having a monocyclic or fused aromatic ring, a content of the near infrared absorbing colorant is 3 mass % or higher with respect to a total solid content of the curable composition, and the photopolymerization initiator does not substantially include a compound having an oxime structure.

The curable composition according to the embodiment of the present invention has excellent storage stability, and thus a cured film having a suppressed variation in spectral characteristics even after a long-term storage can be formed. The mechanism in which the above-described effects can be achieved is not clear but is presumed to be that, by using a photopolymerization initiator including substantially no compound having an oxime structure, the aggregation of the near infrared absorbing colorant is not likely to be inhibited even after a long-term storage of the curable composition such that a cured film having a suppressed variation in spectral characteristics even after storage can be formed. Hereinafter, each of the components of the curable composition according to the embodiment of the present invention will be described.

<<Near Infrared Absorbing Colorant>>

The curable composition according to the embodiment of the present invention includes a near infrared absorbing colorant as a compound that includes a π-conjugated plane having a monocyclic or fused aromatic ring. In the present invention, it is preferable that the near infrared absorbing colorant is a compound having an absorption in a near infrared range (preferably in a wavelength range of 700 to 1,300 nm and more preferably in a wavelength range of 700 to 1,000 nm).

In the present invention, the near infrared absorbing colorant includes the π-conjugated plane having a monocyclic or fused aromatic ring. Therefore, due to an interaction between aromatic rings on the π-conjugated plane of the near infrared absorbing colorant, a J-aggregate of the near infrared absorbing colorant is likely to be formed during the formation of the cured film, and thus a cured film having excellent spectral characteristics in a near infrared range can be formed using the curable composition according to the embodiment of the present invention.

In the present invention, the near infrared absorbing colorant may be a pigment (also referred to as “near infrared absorbing pigment”) or a dye (also referred to as “near infrared absorbing dye”) but is preferably a near infrared absorbing dye. In a case where the near infrared absorbing dye is used, the storage stability of the curable composition tends to be low as compared to a case where the near infrared absorbing pigment is used. According to the present invention, even in a case where the near infrared absorbing dye is used, the storage stability of the curable composition is excellent, and a cured film having a suppressed variation in spectral characteristics even after a long-term storage can be formed. Therefore, in a case where the near infrared absorbing dye is used as the near infrared absorbing colorant, the effects of the present invention are particularly significant. In addition, in the present invention, it is preferable that the near infrared absorbing dye and the near infrared absorbing pigment are used in combination. In a case where the near infrared absorbing dye and the near infrared absorbing pigment are used in combination, a mass ratio near infrared absorbing dye:near infrared absorbing pigment of the near infrared absorbing dye to the near infrared absorbing pigment is preferably 99.9:0.1 to 0.1:99.9, more preferably 99.9:0.1 to 10:90, and still more preferably 99.9:0.1 to 20:80.

In the present invention, a solubility of the near infrared absorbing dye in 100 g of at least one solvent selected from cyclopentanone, cyclohexanone, or dipropylene glycol monomethyl ether at 23° C. is preferably 1 g or higher, more preferably 2 g or higher, and still more preferably 5 g or higher. In addition, a solubility of the near infrared absorbing pigment in 100 g of each solvent of cyclopentanone, cyclohexanone, or dipropylene glycol monomethyl ether at 23° C. is preferably lower than 1 g, more preferably 0.1 g or lower, and still more preferably 0.01 g or lower.

The number of atoms constituting the π-conjugated plane of the near infrared absorbing colorant other than hydrogen is preferably 6 or more, more preferably 14 or more, still more preferably 20 or more, still more preferably 25 or more, and still more preferably 30 or more. For example, the upper limit is preferably 80 or less and more preferably 50 or less.

The number of monocyclic or fused aromatic rings in the π-conjugated plane included in the near infrared absorbing colorant is preferably 2 or more, more preferably 3 or more, still more preferably 4 or more, and still more preferably 5 or more. The upper limit is, for example, preferably 100 or less, more preferably 50 or less, and still more preferably 30 or less. Examples of the aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring including the above-described ring.

In the present invention, the near infrared absorbing colorant has a maximum absorption wavelength preferably in a wavelength range of 700 to 1,300 nm and more preferably in a wavelength range of 700 to 1,000 nm.

In this specification, “having a maximum absorption wavelength in a wavelength range of 700 to 1,300 nm” represents that a wavelength at which the absorbance is maximum is present in a wavelength range of 700 to 1,300 nm in an absorption spectrum of the near infrared absorbing colorant in a solution. Examples of a measurement solvent used for the measurement of the absorption spectra of the near infrared absorbing colorant in the solution include chloroform, methanol, dimethyl sulfoxide, ethyl acetate, and tetrahydrofuran. In a case where the near infrared absorbing colorant is a compound which is soluble in chloroform, chloroform is used as the measurement solvent. In a case where the near infrared absorbing colorant is a compound which is not soluble in chloroform, methanol is used. In addition, in a case where the near infrared absorbing colorant is a compound which is not soluble in chloroform and methanol, dimethyl sulfoxide is used.

The near infrared absorbing colorant has a maximum absorption wavelength in a wavelength range of 700 to 1,000 nm, and a ratio A¹/A² of an absorbance A¹ at a wavelength of 500 nm to an absorbance A² at the maximum absorption wavelength is preferably 0.08 or lower and more preferably 0.04 or lower. According to this aspect, a cured film having excellent visible transparency and infrared shielding properties can be easily manufactured with the curable composition according to the embodiment of the present invention.

In the present invention, in a case where the near infrared absorbing colorant is a dye, it is preferable that the near infrared absorbing colorant has a hydrophobic group. “Hydrophobic group” refers to a group having low polarity and low affinity to water. In a case where the near infrared absorbing colorant has a hydrophobic group, due to a π-π interaction between the π-conjugated planes and an interaction between hydrophobic groups, the near infrared absorbing colorant is arranged to be obliquely shifted in the cured film, and a J-aggregate is likely to be formed. In a case where the near infrared absorbing colorant forms a J-aggregate, the maximum absorption wavelength of the near infrared absorbing colorant is shifted to a wavelength side longer than that in a state the J-aggregate is not formed. Accordingly, in a case where the maximum absorption wavelength of the cured film including the near infrared absorbing colorant is shifted to a wavelength side longer than the maximum absorption wavelength of the near infrared absorbing colorant in the organic solvent, it can be said that the near infrared absorbing colorant forms a J-aggregate in the cured film. Whether or not the near infrared absorbing colorant forms a J-aggregate in a sample can be verified based on, for example, X-ray crystallography data of crystals forming the J-aggregate and X-ray surface analysis of the sample. The shift amount of the maximum absorption wavelength after the formation of the J-aggregate is, for example, preferably 20 nm or longer, more preferably 30 nm or longer, and still more preferably 40 nm or longer. The upper limit is not particularly limited and is, for example, 200 nm or shorter or 180 nm or shorter.

In the present invention, it is preferable that the hydrophobic group is a group represented by Formula (W).

-L-T (W)

In Formula (W), L represents a single bond, a divalent linking group represented by any one of the following Formulae (L-1) to (L-18), or a divalent linking group obtained by bonding two or more selected from the divalent linking groups represented by the following Formulae (L-1) to (L-18).

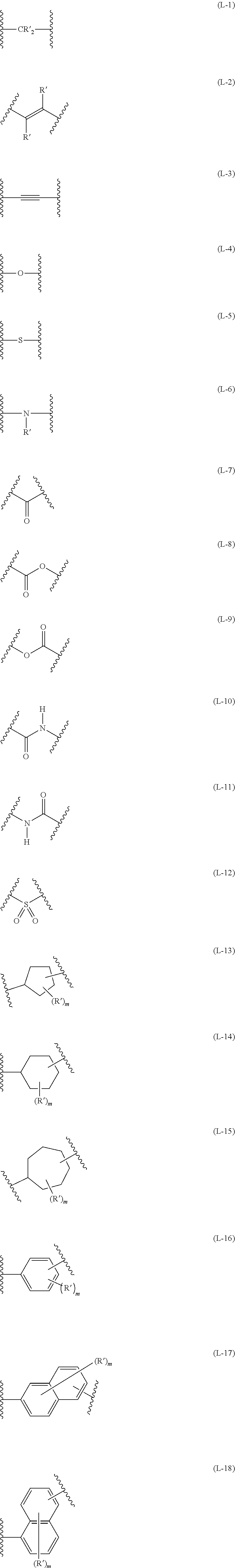

In the formulae, a wave line portion represents a binding site, R′ represents a substituent, and m represents an integer of 0 or more.

The upper limit of m represents the maximum number of substituents in each group. It is preferable that m represents 0.

Examples of the substituent represented by R′ include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR¹R², —COR³, —COOR⁴, —OCOR⁵, —NHCOR⁶, —CONR⁷R⁸, —NHCONR⁹R¹⁰, —NHCOOR¹¹, —SO₂R¹², —SO₂OR¹³, —NHSO₂R¹⁴, and —SO₂NR¹⁵R¹⁶. R¹ to R¹⁶ each independently represent a hydrogen atom, an alkyl group, an alkenyl group, an alkynyl group, an aryl group, or a heteroaryl group.

Examples of the halogen atom include a fluorine atom, a chlorine atom, a bromine atom, and an iodine atom.

The number of carbon atoms in the alkyl group, the alkoxy group, and the alkylthio group is preferably 1 to 20, more preferably 1 to 15, and still more preferably 1 to 8. The alkyl group, the alkoxy group, and the alkylthio group may be linear, branched, or cyclic and is preferably linear or branched and more preferably branched.

The number of carbon atoms in the alkenyl group is preferably 2 to 20, more preferably 2 to 12, and still more preferably 2 to 8. The alkenyl group may be linear, branched, or cyclic and is preferably linear or branched.

The number of carbon atoms in the aryl group is preferably 6 to 30, more preferably 6 to 20, and still more preferably 6 to 12.

The number of carbon atoms in the alkynyl group is preferably 2 to 40, more preferably 2 to 30, and still more preferably 2 to 25. The alkynyl group may be linear, branched, or cyclic and is preferably linear or branched.

The number of carbon atoms in the aryl group included in the aryloxy group and the arylthio group is preferably 6 to 30, more preferably 6 to 20, and still more preferably 6 to 12.

The number of carbon atoms in the aralkyl group is preferably 7 to 40, more preferably 7 to 30, and still more preferably 7 to 25.

The heteroaryl group is preferably a monocycle or a fused ring composed of 2 to 8 rings, and more preferably a monocycle or a fused ring composed of 2 to 4 rings. The number of heteroatoms constituting the ring of the heteroaryl group is preferably 1 to 3. It is preferable that the heteroatoms constituting the ring of the heteroaryl group are a nitrogen atom, an oxygen atom, or a sulfur atom. It is preferable that the heteroaryl group is a 5- or 6-membered ring.

Examples of the heteroaryl group included in the heteroaryloxy group and the heteroarylthio group are as described above, and preferable ranges thereof are also the same.

In Formula (W), T represents an alkyl group, a cyano group, a formyl group, a boryl group, a vinyl group, an ethynyl group, an aryl group, or a heteroaryl group.

The number of carbon atoms in the alkyl group represented by T is preferably 2 to 40. The lower limit is more preferably 5 or more, still more preferably 8 or more, and still more preferably 10 or more. The upper limit is more preferably 32 or lower and still more preferably 28 or lower. The alkyl group may be linear, branched, or cyclic and is preferably linear or branched and more preferably branched.

The number of carbon atoms in the aryl group represented by T is preferably 6 to 30, more preferably 6 to 20, and still more preferably 6 to 12.

The heteroaryl group represented by T may be monocyclic or polycyclic. The number of heteroatoms constituting the ring of the heteroaryl group is preferably 1 to 3. It is preferable that the heteroatoms constituting the ring of the heteroaryl group are a nitrogen atom, an oxygen atom, or a sulfur atom. The number of carbon atoms constituting the ring of the heteroaryl group is preferably 3 to 30, more preferably 3 to 18, and still more preferably 3 to 12.

It is preferable that T represents an alkyl group.

In the present invention, as the near infrared absorbing colorant, at least two compounds having different maximum absorption wavelengths are preferably used. According to this aspect, the waveform of the absorption spectrum of the obtained cured film is wider than that in a case where one near infrared absorbing colorant is used, and the film can shield near infrared light in a wide wavelength range. In a case where at least two compounds having different maximum absorption wavelengths are used, it is preferable that the compounds include at least a first near infrared absorbing colorant having a maximum absorption wavelength in a wavelength range of 700 to 1,000 nm, and a second near infrared absorbing colorant having a maximum absorption wavelength in a wavelength range of 700 to 1,000 nm which is shorter than the maximum absorption wavelength of the first near infrared absorbing colorant, and a difference between the maximum absorption wavelength of the first near infrared absorbing colorant and the maximum absorption wavelength of the second near infrared absorbing colorant is 1 to 150 nm.

In the present invention, as the near infrared absorbing colorant, at least one selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a phthalocyanine compound, a naphthalocyanine compound, or a quaterrylene compound is more preferable, at least one selected from a pyrrolopyrrole compound, a cyanine compound, or a squarylium compound is still more preferable, and a pyrrolopyrrole compound is still more preferable. Examples of the diimmonium compound include a compound described in JP2008-528706A, the content of which is incorporated herein by reference. Examples of the phthalocyanine compound include a compound described in paragraph “0093” of JP2012-077153A, oxytitaniumphthalocyanine described in JP2006-343631A, and a compound described in paragraphs “0013” to “0029” of JP2013-195480A, the contents of which are incorporated herein by reference. Examples of the naphthalocyanine compound include a compound described in paragraph “0093” of JP2012-077153A, the content of which is incorporated herein by reference. In addition, as the cyanine compound, the phthalocyanine compound, the naphthalocyanine compound, the diimmonium compound, or the squarylium compound, for example, a compound described in paragraphs “0010” to “0081” of JP2010-111750A may be used, the content of which is incorporated herein by reference. In addition, the details of the cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference. In addition, a compound described in paragraphs JP2016-146619A can also be used as the near infrared absorbing colorant, the content of which is incorporated herein by reference.

As the pyrrolopyrrole compound, a compound represented by Formula (PP) is preferable. According to this aspect, a film having excellent heat resistance and light fastness can be easily obtained.

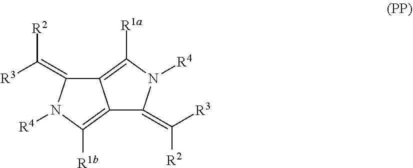

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴ may form a covalent bond or a coordinate bond with at least one selected from the group consisting of R^{1a}, R^{1b}, and R³, and R^{4A} and R^{4B} each independently represent a substituent. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

R^{1a} and R^{1b} each independently represent preferably an aryl group or a heteroaryl group, and more preferably an aryl group. In addition, the alkyl group, the aryl group, and the heteroaryl group represented by R^{1a} to R^{1b} may have a substituent or may be unsubstituted. Examples of the substituent include an alkoxy group, a hydroxy group, a halogen atom, a cyano group, a nitro group, —OCOR¹¹, —SOR¹², and —SO₂R¹³. R¹¹ to R¹³ each independently represent a hydrocarbon group or a heterocyclic group. In addition, examples of the substituent include substituents described in paragraphs “0020” to “0022” of 2009-263614A. In addition, examples of the substituent include the above-described hydrophobic group. For example, as the substituent, an alkoxy group, a hydroxy group, a cyano group, a nitro group, —OCOR¹¹, —SOR¹², or —SO₂R¹³ is preferable. As the group represented by R^{1a} and R^{1b}, an aryl group which has an alkoxy group having a branched alkyl group as a substituent, an aryl group which has a hydroxy group as a substituent, or an aryl group which has a group represented by —OCOR¹¹ as a substituent is preferable. The number of carbon atoms in the branched alkyl group is preferably 3 to 30 and more preferably 3 to 20.

It is preferable that at least one of R² or R³ represents an electron-withdrawing group, and it is more preferable that R² represents an electron-withdrawing group (preferably a cyano group) and R³ represents a heteroaryl group. It is preferable that the heteroaryl group is a 5- or 6-membered ring. In addition, the heteroaryl group is preferably a monocycle or a fused ring, more preferably a monocycle or a fused ring composed of 2 to 8 rings, and still more preferably a monocycle or a fused ring composed of 2 to 4 rings. The number of heteroatoms constituting the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms.

It is preferable that R⁴ represents a hydrogen atom or a group represented by —BR^{4A}R^{4B}. As the substituent represented by R^{4A} and R^{4B}, a halogen atom, an alkyl group, an alkoxy group, an aryl group, or a heteroaryl group is preferable, an alkyl group, an aryl group, or a heteroaryl group is more preferable, and an aryl group is still more preferable. Specific examples of the group represented by —BR^{4A}R^{4B} include a difluoroboron group, a diphenylboron group, a dibutylboron group, a dinaphthylboron group, and a catecholboron group. In particular, a diphenylboron group is preferable.

Specific examples of the compound represented by Formula (PP) include the following compounds. In the following structural formulae, Ph represents a phenyl group. In addition, Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

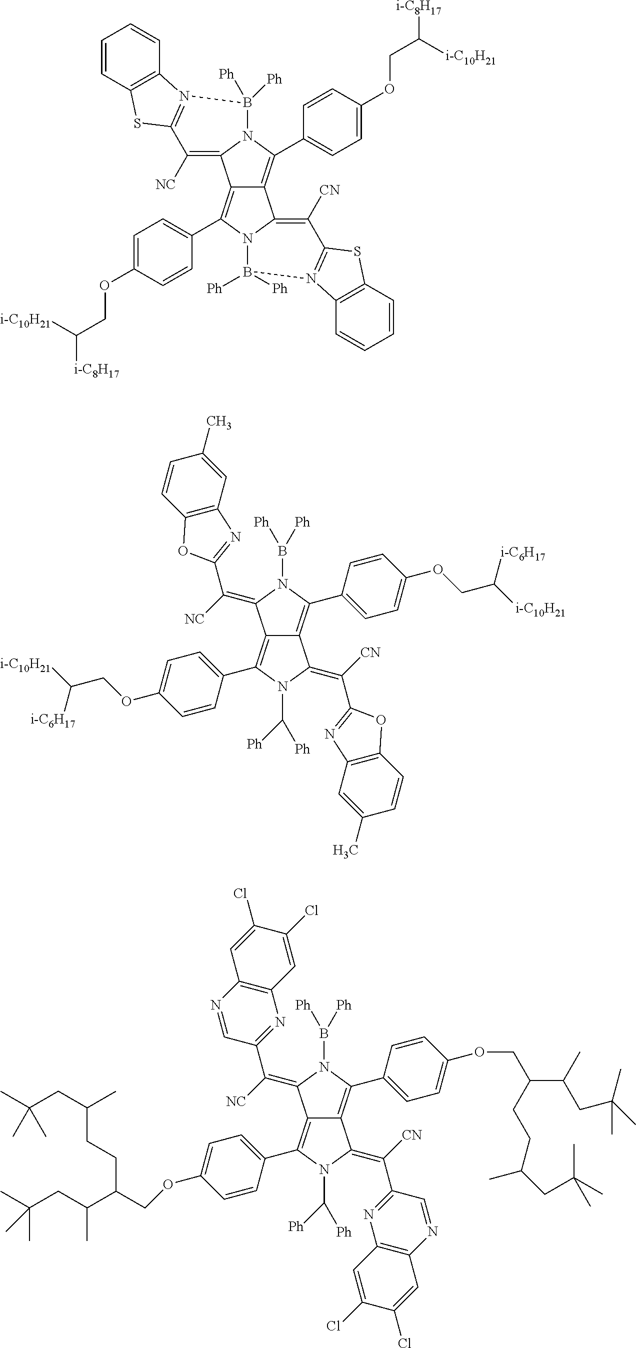

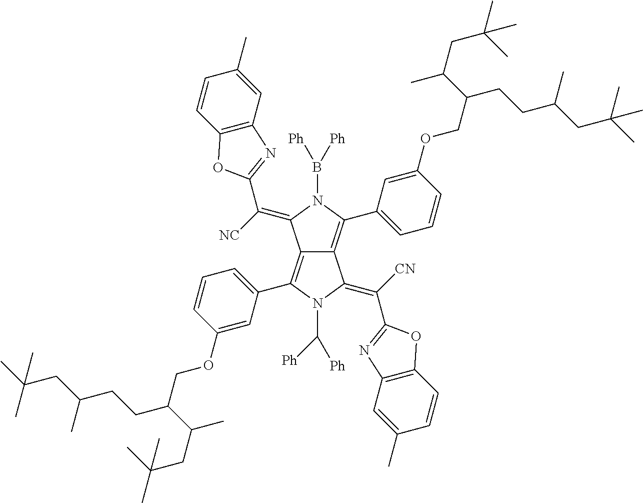 [SMILES: Cc1ccc2oc(/C(C#N)=c3/c4c(-c5cccc(OCC(CCC(C)CC(C)(C)C)C(C)CC(C)(C)C)c5)n(C(c5ccccc5)c5ccccc5)/c(=C(/C#N)c5nc6cc(C)ccc6o5)c4c(-c4cccc(OCC(CCC(C)CC(C)(C)C)C(C)CC(C)(C)C)c4)n3B(c3ccccc3)c3ccccc3)nc2c1]

As the squarylium compound, a compound represented by the following Formula (SQ) is preferable.

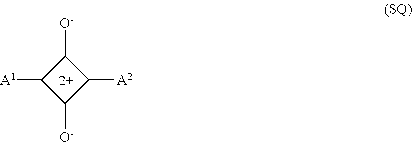

In Formula (SQ), A¹ and A² each independently represent an aryl group, a heteroaryl group, or a group represented by the following Formula (A-1).

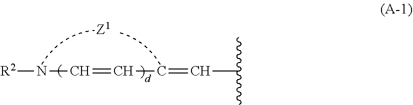

In Formula (A-1), Z¹ represents a non-metal atomic group for forming a nitrogen-containing heterocycle, R² represents an alkyl group, an alkenyl group, or an aralkyl group, d represents 0 or 1, and a wave line represents a direct bond.

The details of Formula (SQ) can be found in paragraphs “0020” to “0049” of JP2011-208101A, the content of which is incorporated herein by reference.

As shown below, cations in Formula (SQ) are present without being localized.

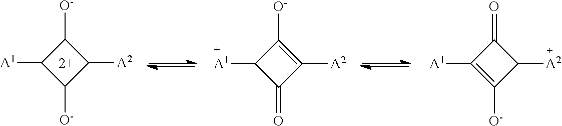

Specific examples of the squarylium compound include the following compounds. Examples of the squarylium compound include a compound described in paragraphs “0044” to “0049” of JP2011-208101A, the content of which is incorporated herein by reference.

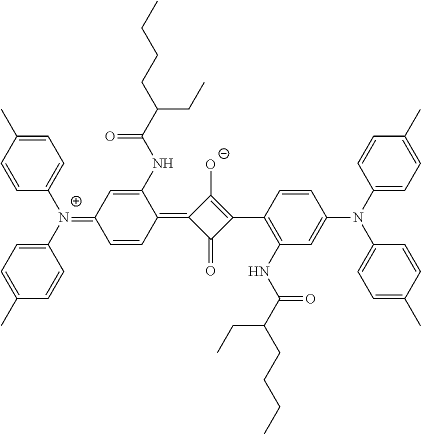 [SMILES: CCCCC(CC)C(=O)NC1=CC(=[N+](c2ccc(C)cc2)c2ccc(C)cc2)C=C/C1=C1\C(=O)C(c2ccc(N(c3ccc(C)cc3)c3ccc(C)cc3)cc2NC(=O)C(CC)CCCC)=C1[O-]]

As the cyanine compound, a compound represented by Formula (C) is preferable.

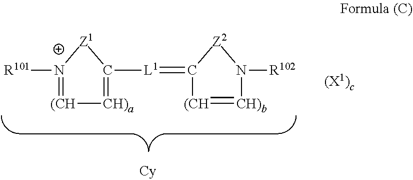

In the formula, Z¹ and Z² each independently represent a non-metal atomic group for forming a 5- or 6-membered nitrogen-containing heterocycle which may be fused, R¹⁰¹ and R¹⁰² each independently represent an alkyl group, an alkenyl group, an alkynyl group, an aralkyl group, or an aryl group, L¹ represents a methine chain including an odd number of methine groups, a and b each independently represent 0 or 1, in a case where a represents 0, a carbon atom and a nitrogen atom are bonded through a double bond, in a case where b represents 0, a carbon atom and a nitrogen atom are bonded through a single bond, in a case where a portion represented by Cy in the formula is a cation site, X¹ represents an anion and c represents the number of X's for balancing charge, in a case where a site represented by Cy in the formula is an anion site, X¹ represents a cation and c represents the number of X¹'s for balancing charge, in a case where charge of a site represented by Cy in the formula is neutralized in a molecule, c represents 0.

Specific examples of the cyanine compound include the following compounds. In addition, examples of the cyanine compound include a compound described in paragraphs “0044” and “0045” of JP2009-108267A, a compound described in paragraphs “0026” to “0030” of JP2002-194040, a compound described in JP2015-172004A, and a compound described in JP2015-172102A, the contents of which are incorporated herein by reference.

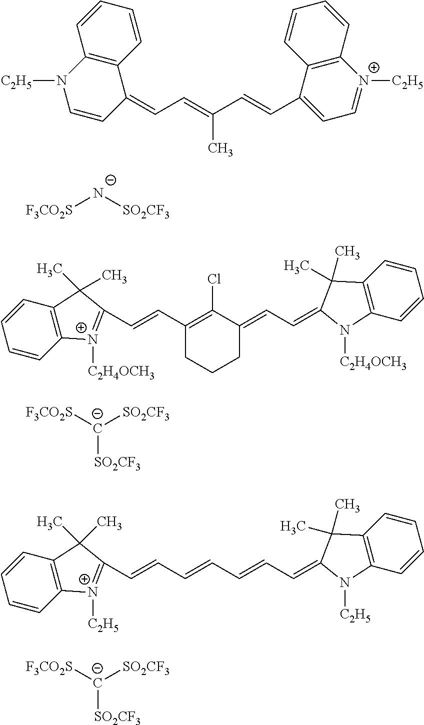

In the present invention, as the near infrared absorbing colorant, a commercially available product can also be used. Examples of the commercially available product include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027 and NK-5060 (manufactured by Hayashibara Co., Ltd.); and YKR-3070 (manufactured by Mitsui Chemicals, Inc.).

In the curable composition according to the embodiment of the present invention, the content of the near infrared absorbing colorant is 3 mass % or higher and preferably 3 to 40 mass % with respect to the total solid content of the curable composition. The upper limit is preferably 35 mass % or lower, and more preferably 30 mass % or lower. The lower limit is preferably 4 mass % or higher and more preferably 5 mass % or higher. As the near infrared absorbing colorants, one kind may be used alone, or two or more kinds may be used. In a case where two or more near infrared absorbing colorants are used in combination, it is preferable that the total content of the two or more near infrared absorbing colorants is in the above-described range.

<<Other Near Infrared Absorbers>>

The curable composition according to the embodiment of the present invention may further include near infrared absorbers (also referred to as “other near infrared absorbers”) other than the near infrared absorbing colorant. Examples of the other near infrared absorbers include an inorganic pigment (inorganic particles). The shape of the inorganic pigment is not particularly limited and may have a sheet shape, a wire shape, or a tube shape irrespective of whether or not the shape is spherical or non-spherical. As the inorganic pigment, metal oxide particles or metal particles are preferable. Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles. Examples of the metal particles include silver (Ag) particles, gold (Au) particles, copper (Cu) particles, and nickel (Ni) particles. In addition, as the inorganic pigment, a tungsten oxide compound can also be used. As the tungsten oxide compound, cesium tungsten oxide is preferable. The details of the tungsten oxide compound can be found in paragraph “0080” of JP2016-006476A, the content of which is incorporated herein by reference.

In a case where the curable composition according to the embodiment of the present invention includes the other near infrared absorbers, the content of the other near infrared absorbers is preferably 0.01 to 50 mass % with respect to the total solid content of the curable composition according to the embodiment of the present invention. The lower limit is preferably 0.1 mass % or higher and more preferably 0.5 mass % or higher. The upper limit is preferably 30 mass % or lower, and more preferably 15 mass % or lower.

In addition, the content of the other near infrared absorbing compounds is preferably 1 to 99 mass % with respect to the total mass of the near infrared absorbing colorant and the other near infrared absorbers. The upper limit is preferably 80 mass % or lower, more preferably 50 mass % or lower, and still more preferably 30 mass % or lower.

In addition, it is also preferable that the curable composition according to the embodiment of the present invention does not substantially include the other near infrared absorbers. Substantially not including the other near infrared absorbers represents that the content of the other near infrared absorbers is preferably 0.5 mass % or lower, more preferably 0.1 mass % or lower, and still more preferably 0 mass % with respect to the total mass of the near infrared absorbing colorant and the other near infrared absorbers.

<<Polymerizable Compounds>>

The curable composition according to the embodiment of the present invention includes a polymerizable compound. As the polymerizable compound, a compound that is polymerizable by the action of a radical is preferable. That is, it is preferable that the polymerizable compound is a radically polymerizable compound. As the polymerizable compound, a compound having one or more groups having an ethylenically unsaturated bond is preferable, a compound having two or more groups having an ethylenically unsaturated bond is more preferable, and a compound having three or more groups having an ethylenically unsaturated bond is still more preferable. The upper limit of the number of the groups having an ethylenically unsaturated bond is, for example, preferably 15 or less and more preferably 6 or less. Examples of the group having an ethylenically unsaturated bond include a vinyl group, a styryl group, a (meth)allyl group, and a (meth)acryloyl group. Among these, a (meth)acryloyl group is preferable. The polymerizable compound is preferably a (meth)acrylate compound having 3 to 15 functional groups and more preferably a (meth)acrylate compound having 3 to 6 functional groups.

The polymerizable compound may be in the form of a monomer or a polymer and is preferably a monomer. The molecular weight of the monomer type polymerizable compound is preferably 100 to 3,000. The upper limit is more preferably 2,000 or lower and still more preferably 1,500 or lower. The lower limit is more preferably 150 or higher and still more preferably 250 or higher. In addition, it is preferable that the polymerizable compound is a compound substantially not having a molecular weight distribution. Here, as the compound substantially not having a molecular weight distribution, a compound having a dispersity (weight-average molecular weight (Mw)/number-average molecular weight (Mn)) of 1.0 to 1.5 is preferable, and a compound having a dispersity 1.0 to 1.3 is more preferable.

Examples of the polymerizable compound can be found in paragraphs “0033” and “0034” of JP2013-253224A, the content of which is incorporated herein by reference. As the polymerizable compound, ethyleneoxy-modified pentaerythritol tetraacrylate (as a commercially available product, NK ESTER ATM-35E manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a compound having a structure in which the (meth)acryloyl group is bonded through an ethylene glycol residue and/or a propylene glycol residue is preferable. In addition, oligomers of the above-described examples can be used. For example, the details of the polymerizable compound can be found in paragraphs “0034” to “0038” of JP2013-253224A, the content of which is incorporated herein by reference. Examples of the compound having an ethylenically unsaturated bond include a polymerizable monomer in paragraph “0477” of JP2012-208494A (corresponding to paragraph “0585” of US2012/0235099A), the contents of which are incorporated herein by reference. In addition, diglycerin ethylene oxide (EO)-modified (meth)acrylate (as a commercially available product, M-460 manufactured by Toagosei Co., Ltd.), pentaerythritol tetraacrylate (A-TMMT manufactured by Shin-Nakamura Chemical Co., Ltd.), or 1,6-hexanediol diacrylate (KAYARAD HDDA manufactured by Nippon Kayaku Co., Ltd.) is also preferable. Oligomers of the above-described examples can be used. For examples, RP-1040 (manufactured by Nippon Kayaku Co., Ltd.) is used.

The polymerizable compound may have an acid group such as a carboxyl group, a sulfo group, or a phosphate group. Examples of a commercially available product of the polymerizable compound having an acid group include ARONIX M-305, M-510, and M-520 (manufactured by Toagosei Co., Ltd.). The acid value of the polymerizable compound having an acid group is preferably 0.1 to 40 mgKOH/g. The lower limit is more preferably 5 mgKOH/g or higher. The upper limit is more preferably 30 mgKOH/g or lower.

In addition, it is also preferable that the polymerizable compound is a compound having a caprolactone structure. The polymerizable compound having a caprolactone structure is not particularly limited as long as it has a caprolactone structure in the molecule thereof, and examples thereof include ε-caprolactone-modified polyfunctional (meth)acrylate obtained by esterification of a polyhydric alcohol, (meth)acrylic acid, and ε-caprolactone, the polyhydric alcohol being, for example, trimethylolethane, ditrimethylolethane, trimethylolpropane, ditrimethylolpropane, pentaerythritol, dipentaerythritol, tripentaerythritol, glycerin, diglycerol, or trimethylolmelamine. Examples of the polymerizable compound having a caprolactone structure can be found in paragraphs “0042” to “0045” of JP2013-253224A, the content of which is incorporated herein by reference. Examples of the polymerizable compound having a caprolactone structure include: DPCA-20, DPCA-30, DPCA-60, and DPCA-120 which are commercially available as KAYARADDPCA series manufactured by Nippon Kayaku Co., Ltd.; SR-494 (manufactured by Sartomer) which is a tetrafunctional acrylate having four ethyleneoxy chains; and TPA-330 which is a trifunctional acrylate having three isobutyleneoxy chains.

As the polymerizable compound, a urethane acrylate described in JP1973-041708B (JP-S48-041708B), JP1976-037193A (JP-S51-037193A), JP1990-032293B (JP-H2-032293B), or JP1990-016765B (JP-H2-016765B), or a urethane compound having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) is also preferable. In addition, the compound which has a group having an ethylenically unsaturated bond can be obtained by using an addition-polymerizable compound having an amino structure or a sulfide structure in the molecules described in JP1988-277653A (JP-S63-277653A), JP1988-260909A (JP-S63-260909A), or JP1989-105238A (JP-H1-105238A). Examples of a commercially available product of the polymerizable compound include URETHANE OLIGOMER UAS-10 and UAB-140 (manufactured by Sanyo-Kokusaku Pulp Co., Ltd.), UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600 and AI-600 (manufactured by Kyoeisha Chemical Co., Ltd.).

The content of the polymerizable compound is preferably 0.1 to 40 mass % with respect to the total solid content of the curable composition. For example, the lower limit is preferably 0.5 mass % or higher and more preferably 1 mass % or higher. For example, the upper limit is more preferably 30 mass % or lower and still more preferably 20 mass % or lower. As the polymerizable compound, one kind may be used alone, or two or more kinds may be used in combination. In a case where two or more polymerizable compounds are used in combination, it is preferable that the total content of the two or more polymerizable compounds is in the above-described range.

<<Photopolymerization Initiator>>

The curable composition according to the embodiment of the present invention includes a photopolymerization initiator. As the photopolymerization initiator, a compound having photosensitivity to light in a range from an ultraviolet range to a visible range is preferable. It is preferable that the photopolymerization initiator is a photoradical polymerization initiator.

The photopolymerization initiator used in the present invention does not substantially include a compound having an oxime structure. In the photopolymerization initiator that does not substantially include a compound having an oxime structure, the content of the compound having an oxime structure is preferably 0.1 mass % or lower, more preferably 0.05 mass % or lower, and still more preferably 0 mass % with respect to the total mass of the photopolymerization initiator.

As the photopolymerization initiator used in the present invention, any compound other than the compound having an oxime structure (hereinafter, also referred to as “oxime compound”) can be preferably used. Examples of the compound other than the oxime compound include an alkylphenone compound, an acylphosphine oxide compound, a biimidazole compound, and a triazine compound. Among these, an alkylphenone compound, an acylphosphine oxide compound, or a biimidazole compound is preferable, an alkylphenone compound or an acylphosphine oxide compound is more preferable, and an alkylphenone compound is still more preferable from the viewpoint of low volatility.

In addition, as the alkylphenone compound, from the viewpoint of a high absorption coefficient at a wavelength of 365 nm, a benzyldimethylketal compound, an α-hydroxyalkylphenone compound, or an α-aminoalkylphenone compound is preferable. Among these, an α-aminoalkylphenone compound is more preferable.

Examples of the benzyldimethylketal compound include 2,2-dimethoxy-2-phenylacetophenone. Examples of a commercially available product include IRGACURE-651 (manufactured by BASF SE).

Examples of the α-hydroxyalkylphenone compound include a compound represented by the following Formula (V-1).

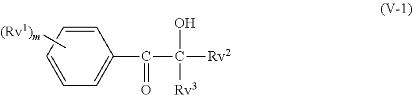

In the formula, Rv¹ represents a substituent, Rv² and Rv³ each independently represent a hydrogen atom or a substituent, Rv² and Rv³ bonded to each other to form a ring, and m represents an integer of 0 to 4.

Examples of the substituent represented by RV¹ include an alkyl group having 1 to 10 carbon atoms, an alkoxy group having 1 to 10 carbon atoms, and an aralkyl group having 7 to 20 carbon atoms. The alkyl group and the alkoxy group are preferably linear or branched and more preferably linear. The alkyl group, the alkoxy group, and the aralkyl group represented by Rv1 may be unsubstituted or may have a substituent. Examples of the substituent include a hydroxy group.

Rv² and Rv³ each independently represent a hydrogen atom or a substituent. As the substituent, an alkyl group having 1 to 10 carbon atoms or an aryl group having 6 to 20 carbon atoms is preferable. In addition, Rv2 and Rv3 may be bonded to each other to form a ring (preferably a ring having 4 to 8 carbon atoms and more preferably an aliphatic ring having 4 to 8 carbon atoms). The alkyl group is preferably linear or branched and more preferably linear.

Specific examples of the α-hydroxyalkylphenone compound include 1-hydroxy-cyclohexyl-phenyl-ketone, 2-hydroxy-2-methyl-1-phenyl-propane-1-one, 1-[4-(2-hydroxyethoxy)-phenyl]-2-hydroxy-2-methyl-1-propane-1-one, and 2-hydroxy-1-{4-[4-(2-hydroxy-2-methyl-propionyl)-benzyl]phenyl}-2-methyl-propane-1-one. Examples of a commercially available product of the α-hydroxyalkylphenone compound include IRGACURE-184, DAROCUR-1173, IRGACURE-500, IRGACURE-2959, and IRGACURE-127 (all of which are manufactured by BASF SE).

Examples of the α-aminoalkylphenone compound include a compound represented by the following Formula (V-2).

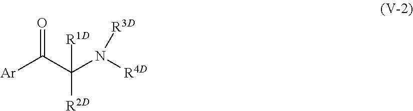

In the formula, Ar represents a phenyl group which is substituted with —SR¹³ or —N(R^{7E})(R^{8E}), and R¹³ represents a hydrogen atom or an alkyl group having 1 to 12 carbon atoms.

R^{1D} and R^{2D} each independently represent an alkyl group having 1 to 8 carbon atoms. R^{1D} and R^{2D} may be bonded to each other to form a ring.

The alkyl group represented by R^{1D} and R^{2D} may be linear, branched, or cyclic and is preferably linear or branched.

The alkyl group represented by R^{1D} and R^{2D} may be unsubstituted or may have a substituent. Examples of the substituent include an aryl group, a heterocyclic group, a nitro group, a cyano group, a halogen atom, —OR^{Y1}, —SR^{Y1}, —COR^{Y1}, —COOR^{Y1}, —OCOR^{Y1}, —NR^{Y1}R^{Y2}, —NHCOR^{Y1}, —CONR^{Y1}R^{Y2}, —NHCONR^{Y1}R^{Y2}, —NHCOOR^{Y1}, —SO₂R^{Y1}, —SO₂OR^{Y1}, and —NHSO₂R^{Y1}. R^{Y1} and R² each independently represent a hydrogen atom, an alkyl group, an aryl group, or a heterocyclic group.

Examples of the halogen atom include a fluorine atom, a chlorine atom, a bromine atom, and an iodine atom.

The number of carbon atoms in the alkyl group represented by R¹ and R² is preferably 1 to 20. The alkyl group may be linear, branched, or cyclic and is preferably linear or branched.

The number of carbon atoms in the aryl group as the substituent and the aryl group represented by R^{Y1} and R^{Y2} is preferably 6 to 20, more preferably 6 to 15, and still more preferably 6 to 10. The aryl group may be a monocycle or a fused ring.

It is preferable that the heterocyclic group represented by R^{Y1} and R^{Y2} is a 5- or 6-membered ring. The heterocyclic group may be a monocycle or a fused ring. The number of carbon atoms constituting the heterocyclic group is preferably 3 to 30, more preferably 3 to 18, and still more preferably 3 to 12. The number of heteroatoms constituting the heterocyclic group is preferably 1 to 3. It is preferable that the heteroatoms constituting the heterocyclic group are a nitrogen atom, an oxygen atom, or a sulfur atom.

R^{3D} and R^{4D} each independently represent a hydrogen atom or an alkyl group having 1 to 12 carbon atoms. R^{3D} and R^{4D} may be bonded to each other to form a ring. In a case where R^{3D} and R^{4D} are bonded to each other to form a ring, R^{3D} and R^{4D} may be bonded directly to form a ring or may be bonded through —CO—, —O—, or —NH— to form a ring. Examples of the ring which is formed by R^{3D} and R^{4D} being bonded through —O— include a morpholine ring.

R^{7E} and R^{8E} each independently represent a hydrogen atom or an alkyl group having 1 to 12 carbon atoms. R^{7E} and R^{8E} may be bonded to each other to form a ring. In a case where R^{7E} and R^{8E} are bonded to each other to form a ring, R^{7E} and R^{8E} may be bonded directly to form a ring or may be bonded through —CO—, —O—, or —NH— to form a ring. Examples of the ring which is formed by R^{7E} and R^{8E} being bonded through —O— include a morpholine ring.

Specific examples of the α-aminoalkylphenone compound include 2-methyl-1-(4-methylthiophenyl)-2-morpholinopropane-1-one, 2-benzyl-2-dimethylamino-1-(4-morpholinophenyl)-1-butanone, and 2-dimethylamino-2-[(4-methylphenyl)methyl]-1-[4-(4-morpholinyl)phenyl]-1-butanone. Examples of a commercially available product of the α-aminoalkylphenone compound include IRGACURE-907, IRGACURE-369, and IRGACURE-379 (all of which are manufactured by BASF SE).

Examples of the acylphosphine oxide compound include 2,4,6-trimethylbenzoyl-diphenyl-phosphine oxide and bis(2,4,6-trimethylbenzoyl)-phenylphosphine oxide. Examples of a commercially available product of the acylphosphine oxide compound include IRGACURE-819 and IRGACURE-TPO (all of which are manufactured by BASF SE).

Examples of the biimidazole compound include a hexaarylbisimidazole compound. Specific examples of the hexaarylbisimidazole compound include compounds described in paragraphs “0179” and “0180” of JP2015-124378A. Examples of a commercially available product include B-CIM (manufactured by Hodogaya Chemical Co., Ltd.).

Examples of the triazine compound include 2,4-bis(trichloromethyl)-6-p-methoxyphenyl-s-triazine, 2,4-bis(trichloromethyl)-6-p-methoxystyryl-s-triazine, 2,4-bis(trichloromethyl)-6-(1-p-dimethylaminophenyl)-1,3-butadienyl-s-triazine, 2,4-bis(trichloromethyl)-6-biphenyl-s-triazine, 2,4-bis(trichloromethyl)-6-(p-methylbiphenyl)-s-triazine, p-hydroxyethoxy styryl-2,6-di(trichloromethyl)-s-triazine, methoxystyryl-2,6-di(trichloromethyl)-s-triazine, 3,4-dimethoxystyryl-2,6-di(trichloromethyl)-s-triazine, 4-benzoxolane-2,6-di(trichloromethyl)-s-triazine, 4-(o-bromo-p-N,N-(diethoxycarbonylamino)-phenyl)-2,6-di(chloromethyl)-s-triazine, and 4-(p-N,N-(diethoxycarbonylamino)-phenyl)-2,6-di(chloromethyl)-s-triazine. In addition, examples of a commercially available product of the triazine compound include TRIAZINE PP (manufactured by Nihon Siber Hegner K. K.).

The molecular weight of the photopolymerization initiator is preferably 200 to 700. The lower limit is more preferably 400 or higher and still more preferably 500 or higher. The upper limit is more preferably 600 or lower and still more preferably 500 or lower.

The photopolymerization initiator is preferably a compound having a maximum absorption wavelength in a wavelength range of 350 to 500 nm and more preferably a compound having a maximum absorption wavelength in a wavelength range of 360 to 480 nm. In addition, it is preferable that the photopolymerization initiator is a compound having a high absorbance at 365 nm and 405 nm.

The molar absorption coefficient of the photopolymerization initiator at 365 nm or 405 nm is preferably 20 to 300,000, more preferably 50 to 100,000, and still more preferably 70 to 20,000 from the viewpoint of sensitivity.

The molar absorption coefficient of the photopolymerization initiator can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

The content of the photopolymerization initiator is preferably 0.1 to 50 mass % with respect to the total solid content of the curable composition. For example, the lower limit is preferably 0.5 mass % or higher and more preferably 1 mass % or higher. For example, the upper limit is more preferably 30 mass % or lower and still more preferably 20 mass % or lower.

In addition, in the curable composition according to the embodiment of the present invention, the content of the photopolymerization initiator is preferably 0.2 to 40 parts by mass with respect to 100 parts by mass of the polymerizable compound.

As the photopolymerization initiator, one kind may be used alone, or two or more kinds may be used in combination. In a case where two or more photopolymerization initiators are used in combination, it is preferable that the total content of the two or more photopolymerization initiators is in the above-described range.

<<Resin>>

It is preferable that the curable composition according to the embodiment of the present invention includes a resin. The resin is added, for example, in order to disperse particles of the pigments and the like in the composition or to be added as a binder. The resin which is mainly used to disperse particles of the pigments and the like will also be called a dispersant. However, the above-described uses of the resin are merely exemplary, and the resin can be used for purposes other than the uses.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an epoxy resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used. As the cyclic olefin resin, a norbornene resin can be preferably used from the viewpoint of improving heat resistance. Examples of a commercially available product of the norbornene resin include ARTON series (for example, ARTON F4520, manufactured by JSR Corporation). Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound. In addition, for example, as the epoxy resin, MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer) can also be used. In addition, as the resin, a resin described in Examples of WO2016/088645A can also be used.

The resin used in the present invention may have an acid group. Examples of the acid group include a carboxyl group, a phosphate group, a sulfo group, and a phenolic hydroxy group. Among these, a carboxyl group is preferable. Among these acid groups, one kind may be used alone, or two or more kinds may be used in combination. The resin having an acid group can also be used as an alkali-soluble resin.

As the resin having an acid group, a polymer having a carboxyl group at a side chain is preferable. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (JP-H10-300922A) such as N-phenylmaleimide or N-cyclohexylmaleimide. Among these monomers which are copolymerizable with the (meth)acrylic acid, one kind may be used alone, or two or more kinds may be used in combination.

The resin having an acid group may further have a polymerizable group. Examples of the polymerizable group include a (meth)allyl group and a (meth)acryloyl group. Examples of a commercially available product of the resin include DIANAL NR series (manufactured by Mitsubishi Rayon Co., Ltd.), PHOTOMER 6173 (a carboxyl group-containing polyurethane acrylate oligomer; manufactured by Diamond Shamrock Co., Ltd.), VISCOAT R-264 and KS Resist 106 (both of which are manufactured by Osaka Organic Chemical Industry Ltd.), CYCLOMER P series (for example, ACA230AA) and PLAKCEL CF200 series (both of which manufactured by Daicel Corporation), EBECRYL 3800 (manufactured by Daicel-UCB Co., Ltd.), and ACRYCURE RD-F8 (manufactured by Nippon Shokubai Co., Ltd.).

As the resin having an acid group, a copolymer including benzyl (meth)acrylate and (meth)acrylic acid; a copolymer including benzyl (meth)acrylate, (meth)acrylic acid, and 2-hydroxyethyl (meth)acrylate; or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer that includes a repeating unit derived from monomer components including a compound represented by the following Formula (ED1) and/or a compound represented by the following Formula (ED2) (hereinafter, these compounds will also be referred to as “ether dimer”) is also preferable.

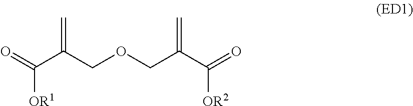

In Formula (ED1), R¹ and R² each independently represent a hydrogen atom or a hydrocarbon group having 1 to 25 carbon atoms which may have a substituent.

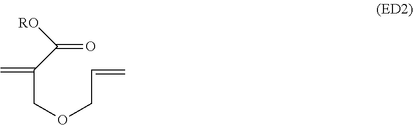

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph “0317” of JP2013-029760A, the content of which is incorporated herein by reference. Among these ether dimers, one kind may be used alone, or two or more kinds may be used in combination.

The resin having an acid group may include a repeating unit which is derived from a compound represented by the following Formula (X).

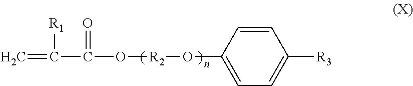

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or higher and more preferably 70 mgKOH/g or higher. The upper limit is preferably 150 mgKOH/g or lower and more preferably 120 mgKOH/g or lower.

Examples of the resin having an acid group include resins having the following structures. In the following structural formulae, Me represents a methyl group.

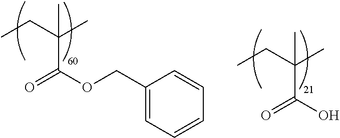

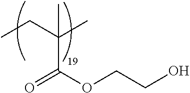

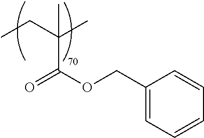

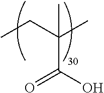

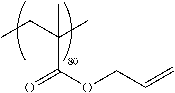

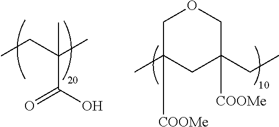

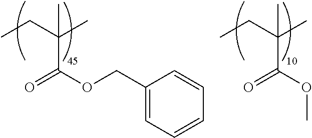

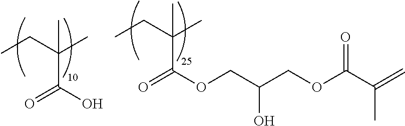

In the curable composition according to the embodiment of the present invention, as the resin, a resin having a repeating unit represented by any one of Formulae (A3-1) to (A3-7) is also preferably used.

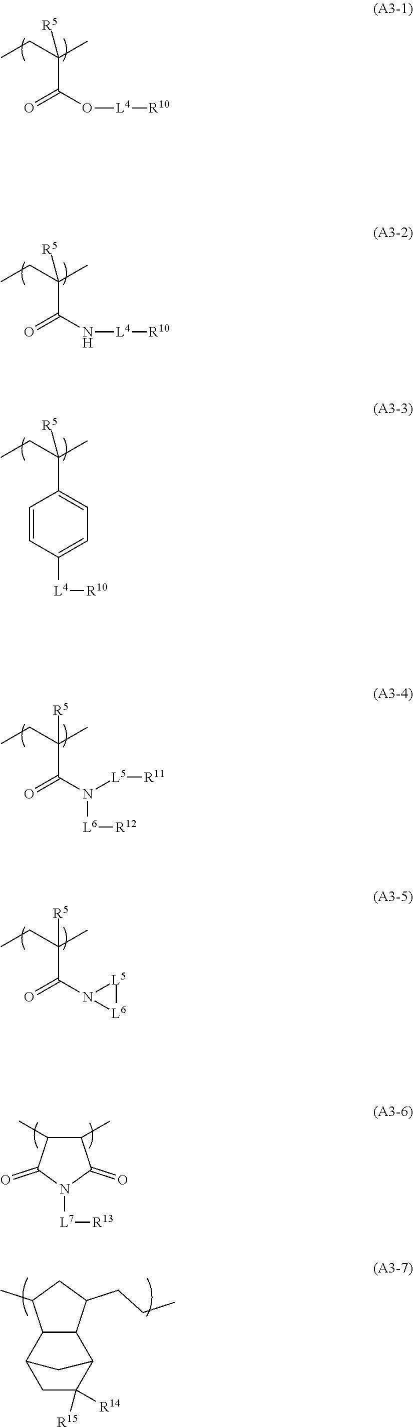

In the formulae, R⁵ represents a hydrogen atom or an alkyl group, L⁴ to L⁷ each independently represent a single bond or a divalent linking group, and R¹⁰ to R¹³ each independently represent an alkyl group or an aryl group. R¹⁴ and R¹⁵ each independently represent a hydrogen atom or a substituent.

R⁵ represents a hydrogen atom or an alkyl group. The number of carbon atoms in the alkyl group is preferably 1 to 5, more preferably 1 to 3, and still more preferably 1. It is preferable that R⁵ represents a hydrogen atom or a methyl group.

L⁴ to L⁷ each independently represent a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group including a combination thereof.

The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

The alkyl group represented by R¹⁰ to R¹³ may be linear, branched, or cyclic and is preferably cyclic. The alkyl group may have a substituent or may be unsubstituted. The number of carbon atoms in the alkyl group is preferably 1 to 30, more preferably 1 to 20, and still more preferably 1 to 10. The number of carbon atoms in the aryl group represented by R¹⁰ to R¹³ is preferably 6 to 18, more preferably 6 to 12, and still more preferably 6. It is preferable that R¹⁰ represents a cyclic alkyl group or an aryl group. It is preferable that R¹¹ and R¹² represent a linear or branched alkyl group. It is preferable that R¹³ represents a linear alkyl group, a branched alkyl group, or an aryl group.

Examples of the substituent represented by R¹⁴ and R¹⁵ include a halogen atom, a cyano group, a nitro group, an alkyl group, an alkenyl group, an alkynyl group, an aryl group, a heteroaryl group, an aralkyl group, an alkoxy group, an aryloxy group, a heteroaryloxy group, an alkylthio group, an arylthio group, a heteroarylthio group, —NR^{a1}R^{a2}, —COR^{a3}, —COOR^{a4}, —OCOR^{a5}, —NHCOR^{a6}, —CONR^{a7}R^{a8}, —NHCONR^{a9}R^{a10}, —NHCOOR^{a11}, —SO₂R^{a12}, —SO₂OR^{a13}, —NHSO₂R^{a14}, and —SO₂NR^{a15}R^{a16}, R^{a1} and R^{a16} each independently represent a hydrogen atom, an alkyl group, an alkenyl group, an alkynyl group, an aryl group, or a heteroaryl group. In particular, it is preferable that at least one of R¹⁴ or R¹⁵ represents a cyano group or —COOR^{a4}. It is preferable that R^{a4} represents a hydrogen atom, an alkyl group, or an aryl group.

Examples of a commercially available product of the resin having a repeating unit represented by Formula (A3-7) include ARTON F4520 (manufactured by JSR Corporation). In addition, the details of the resin having a repeating unit represented by Formula (A3-7) can be found in paragraphs “0053” to “0075” and “0127” to “0130” of JP2011-100084A, the content of which is incorporated herein by reference.

The curable composition according to the embodiment of the present invention may include a resin as a dispersant. In particular, in a case where a pigment is used, it is preferable that the composition includes a dispersant. Examples of the dispersant include an acidic dispersant (acidic resin) and a basic dispersant (basic resin). Here, the acidic dispersant (acidic resin) refers to a resin in which the amount of an acid group is more than the amount of a basic group. In a case where the sum of the amount of an acid group and the amount of a basic group in the acidic dispersant (acidic resin) is represented by 100 mol %, the amount of the acid group in the acidic resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the basic resin is preferably higher than 50 mol %. The basic group in the basic dispersant is preferably an amino group.

It is preferable that the resin A used as the dispersant further includes a repeating unit having an acid group. By the resin, which is used as the dispersant, including the repeating unit having an acid group, in a case where a pattern is formed using a photolithography method, the amount of residues formed in an underlayer of a pixel can be reduced.

It is preferable that the resin used as the dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

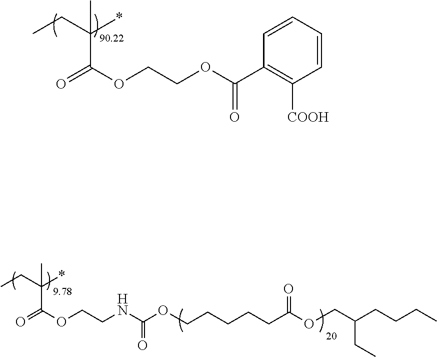

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain Y having 40 to 10,000 atoms and has a basic nitrogen atom at at least either a main chain or a side chain, is preferable. The basic nitrogen atom is not particularly limited as long as it is a nitrogen atom exhibiting basicity. The oligoimine dispersant can be found in the description of paragraphs “0102” to “0166” of JP2012-255128A, the content of which is incorporated herein by reference. Specific examples of the oligoimine dispersant are as follows. The following resin may also be a resin having an acid group (alkali-soluble resin). In addition, as the oligoimine dispersant, a resin described in paragraphs “0168” to “0174” of JP2012-255128A can be used.

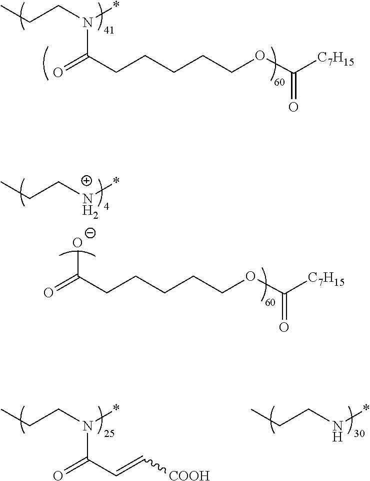

The dispersant is available as a commercially available product, and specific examples thereof include Disperbyk-111 (manufactured by BYK Chemie) and SOLSPERSE 76500 (manufactured by Lubrication Technology Inc.). In addition, a pigment dispersant described in paragraphs “0041” to “0130” of JP2014-130338A can also be used, the content of which is incorporated herein by reference. In addition, the resin having an acid group or the like can also be used as a dispersant.

In the curable composition according to the embodiment of the present invention, the content of the resin is preferably 1 to 80 mass % with respect to the total solid content of the curable composition according to the embodiment of the present invention. The lower limit is preferably 5 mass % or higher and more preferably 7 mass % or higher. The upper limit is preferably 50 mass % or lower and more preferably 30 mass % or lower.

In addition, in a case where the curable composition includes a dispersant as the resin, the content of the dispersant is preferably 0.1 to 40 mass % with respect to the total solid content of the curable composition. The upper limit is preferably 20 mass % or lower, and more preferably 10 mass % or lower. The lower limit is preferably 0.5 mass % or higher and more preferably 1 mass % or higher. The content of the dispersant is preferably 1 to 100 parts by mass with respect to 100 parts by mass of the pigment. The upper limit is preferably 80 parts by mass or less and more preferably 60 parts by mass or less. The lower limit is preferably 2.5 parts by mass or more and more preferably 5 parts by mass or more.

<<Epoxy Curing Agent>>

In a case where the curable composition according to the embodiment of the present invention includes an epoxy resin, it is preferable that the composition further includes an epoxy curing agent. Examples of the epoxy curing agent include an amine compound, an acid anhydride compound, an amide compound, a phenol compound, a polycarboxylic acid, and a thiol compound. From the viewpoints of heat resistance and transparency of a cured product, as the epoxy curing agent, a polycarboxylic acid is preferable, and a compound having two or more carboxylic anhydride groups in a molecule is most preferable. Specific examples of the epoxy curing agent include butanedioic acid. As the epoxy curing agent, a compound described in paragraphs “0072” to “0078” of JP2016-075720A can also be used, the content of which is incorporated herein by reference.

The content of the epoxy curing agent is preferably 0.01 to 20 parts by mass, more preferably 0.01 to 10 parts by mass, and still more preferably 0.1 to 6.0 parts by mass with respect to 100 parts by mass of the epoxy resin.

<<Chromatic Colorant>>

The curable composition according to the embodiment of the present invention may include a chromatic colorant. In the present invention, “chromatic colorant” denotes a colorant other than a white colorant and a black colorant. It is preferable that the chromatic colorant is a colorant having an absorption in a wavelength range of 400 nm or longer and shorter than 650 nm.

In the present invention, the chromatic colorant may be a pigment or a dye. As the pigment, an organic pigment is preferable. Examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments); C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, and 59 (all of which are green pigments);

C.I. Pigment Violet 1, 19, 23, 27, 32, 37, and 42 (all of which are violet pigments); and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

As the dye, well-known dyes can be used without any particular limitation. In terms of a chemical structure, a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, or a pyrromethene dye can be used. In addition, a polymer of the above-described dyes may be used. In addition, dyes described in JP2015-028144A and JP2015-034966A can also be used.

In a case where the curable composition according to the embodiment of the present invention includes a chromatic colorant, it is preferable that the content of the chromatic colorant is 0.1 to 70 mass % with respect to the total solid content of the curable composition according to the embodiment of the present invention. The lower limit is preferably 0.5 mass % or higher and more preferably 1.0 mass % or higher. The upper limit is preferably 60 mass % or lower, and more preferably 50 mass % or lower.

The content of the chromatic colorant is preferably 10 to 1000 parts by mass and more preferably 50 to 800 parts by mass with respect to 100 parts by mass of the near infrared absorbing colorant.

In addition, the total content of the chromatic colorant and the near infrared absorbing colorant is preferably 1 to 80 mass % with respect to the total solid content of the curable composition according to the embodiment of the present invention. The lower limit is preferably 5 mass % or higher and more preferably 10 mass % or higher. The upper limit is preferably 70 mass % or lower, and more preferably 60 mass % or lower.

In a case where the curable composition according to the embodiment of the present invention includes two or more chromatic colorants, it is preferable that the total content of the two or more chromatic colorants is in the above-described range.

<<Coloring Material that Allows Transmission of Infrared Light and Shields Visible Light>>

The curable composition according to the embodiment of the present invention may also include the coloring material that allows transmission of infrared light and shields visible light (hereinafter, also referred to as “coloring material that shields visible light”).

In the present invention, it is preferable that the coloring material that shields visible light is a coloring material that absorbs light in a wavelength range of violet to red. In addition, in the present invention, it is preferable that the coloring material that shields visible light is a coloring material that shields light in a wavelength range of 450 to 650 nm. In addition, it is preferable that the coloring material that shields visible light is a coloring material that allows transmission of light in a wavelength range of 900 to 1300 nm.

In the present invention, it is preferable that the coloring material that shields visible light satisfies at least one of the following requirement (A) or (B).

(A): The coloring material that shields visible light includes two or more chromatic colorants, and a combination of the two or more chromatic colorants forms black.

(B): The coloring material that shields visible light includes an organic black colorant.

Examples of the chromatic colorant are as described above. Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include a compound described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available.

In a case where a combination of two or more chromatic colorants forms black, examples of the combination of chromatic colorants are as follows.

(1) An aspect in which the coloring material that shields visible light includes a yellow colorant, a blue colorant, a violet colorant, and a red colorant

(2) An aspect in which the coloring material that shields visible light includes a yellow colorant, a blue colorant, and a red colorant

(3) An aspect in which the coloring material that shields visible light includes a yellow colorant, a violet colorant, and a red colorant

(4) An aspect in which the coloring material that shields visible light includes a yellow colorant and a violet colorant

(5) An aspect in which the coloring material that shields visible light includes a green colorant, a blue colorant, a violet colorant, and a red colorant

(6) An aspect in which the coloring material that shields visible light includes a violet colorant and an orange colorant

(7) An aspect in which the coloring material that shields visible light includes a green colorant, a violet colorant, and a red colorant

(8) An aspect in which the coloring material that shields light in the visible range includes a green colorant and a red colorant

In a case where the curable composition according to the embodiment of the present invention includes the coloring material that shields visible light, the content of the coloring material that shields visible light is preferably 60 mass % or lower, more preferably 50 mass % or lower, still more preferably 30 mass % or lower, still more preferably 20 mass % or lower, and still more preferably 15 mass % or lower with respect to the total solid content of the curable composition. The lower limit is, for example, 0.01 mass % or higher or 0.5 mass % or higher.

<<Pigment Derivative>>

The curable composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

In Formula (B1), P represents a colorant structure, preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, or a benzoxazole colorant structure, more preferably at least one selected from a pyrrolopyrrole colorant structure, a diketo pyrrolopyrrole colorant structure, a quinacridone colorant structure, or a benzimidazolone colorant structure, and still more preferably a pyrrolopyrrole colorant structure.

In Formula (B1), L represents a single bond or a linking group. The linking group is preferably a group composed of 1 to 100 carbon atoms, 0 to 10 nitrogen atoms, 0 to 50 oxygen atoms, 1 to 200 hydrogen atoms, and 0 to 20 sulfur atoms, and may be unsubstituted or may further have a substituent.

In Formula (B1), X represents an acid group, a basic group, a group having a salt structure, or a phthalimidomethyl group. Among these, an acid group or a basic group is preferable. Examples of the acid group include a carboxyl group and a sulfo group. Examples of the basic group include an amino group.

Examples of the pigment derivative include compounds having the following structures. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, and paragraphs “0063” to “0094” of WO2012/102399A can be used, the content of which is incorporated herein by reference.

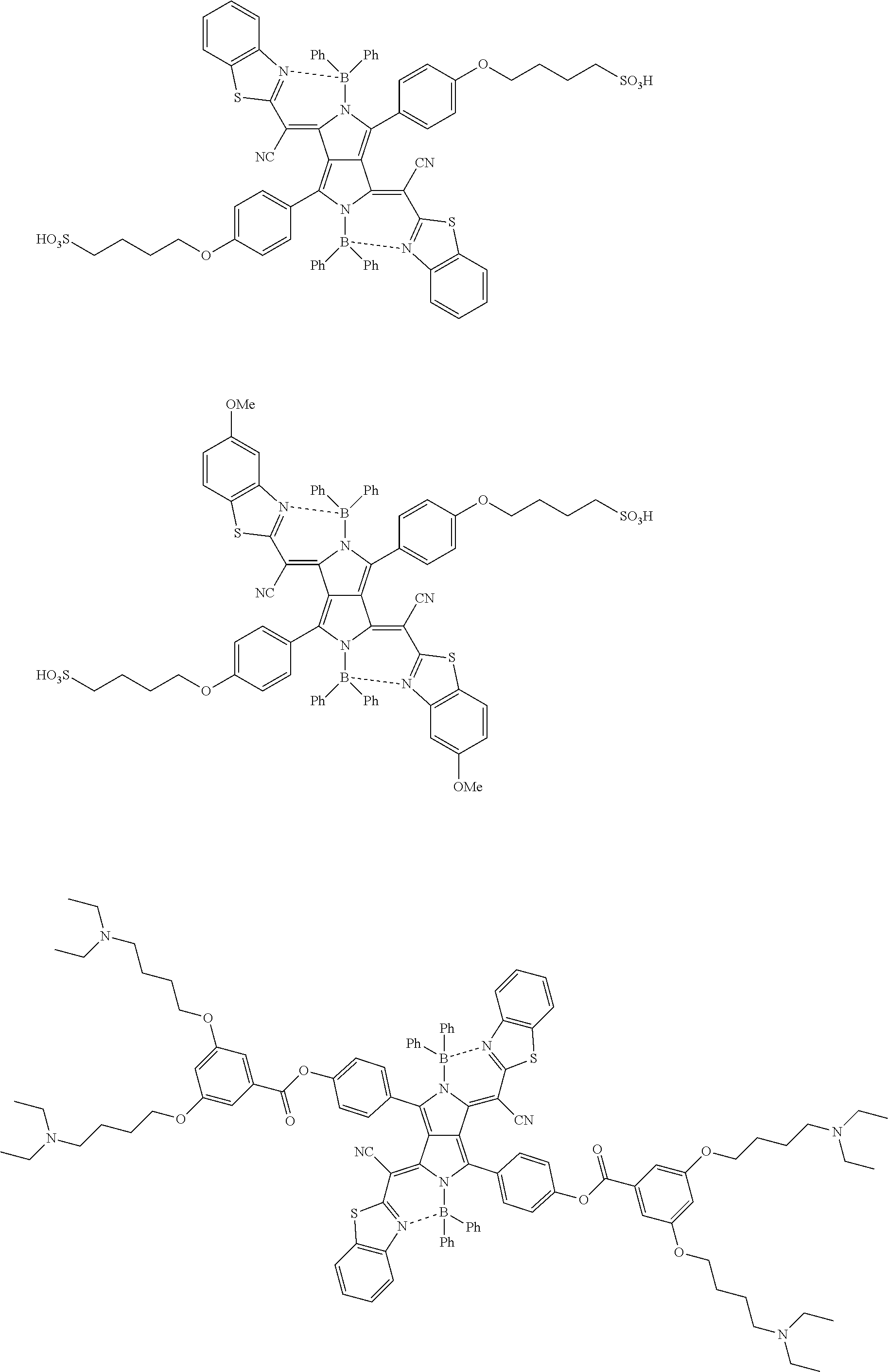

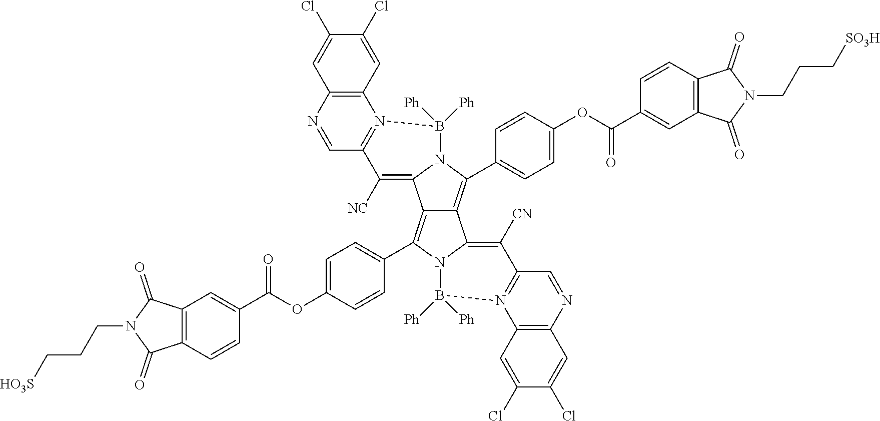

In a case where the curable composition according to the embodiment of the present invention includes the pigment derivative, the content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be effectively suppressed. As the pigment derivative, one kind may be used alone, or two or more kinds may be used in combination. In a case where two or pigment derivatives are used in combination, it is preferable that the total content of the two or more pigment derivatives is in the above-described range.

<<Solvent>>

The curable composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent is preferably 10 to 97 mass % with respect to the total mass of the curable composition. The lower limit is preferably 30 mass % or higher, more preferably 40 mass % or higher, still more preferably 50 mass % or higher, still more preferably 60 mass % or higher, and still more preferably 70 mass % or higher. The upper limit is preferably 96 mass % or lower and more preferably 95 mass % or lower.

<<Polymerization Inhibitor>>

The curable composition according to the embodiment of the present invention may include a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), and N-nitrosophenylhydroxyamine salt (for example, an ammonium salt or a cerium (III) salt). Among these, p-methoxyphenol is preferable. The content of the polymerization inhibitor is preferably 0.001 to 5 mass % with respect to the total solid content of the curable composition.

<<Silane Coupling Agent>>

The curable composition according to the embodiment of the present invention may include a silane coupling agent. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a styryl group, a (meth)acryloyl group, a mercapto group, an epoxy group, an oxetanyl group, an amino group, an ureido group, a sulfide group, an isocyanate group, and a phenyl group. Among these, a (meth)acryloyl group or an epoxy group is preferable. Examples of the silane coupling agent include a compound described in paragraphs “0018” to “0036” of JP2009-288703A and a compound described in paragraphs “0056” to “0066” of JP2009-242604A, the contents of which are incorporated herein by reference.

The content of the silane coupling agent is preferably 0.01 to 15.0 mass % and more preferably 0.05 to 10.0 mass % with respect to the total solid content of the curable composition. As the silane coupling agent, one kind may be used alone, or two or more kinds may be used. In a case where two or more silane coupling agents are used in combination, it is preferable that the total content of the two or more silane coupling agents is in the above-described range.

<<Surfactant>>

The curable composition according to the embodiment of the present invention may include a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the curable composition according to the embodiment of the present invention containing a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Specific examples of the fluorine surfactant include a surfactant described in paragraphs “0060” to “0064” of JP2014-041318A (paragraphs “0060” to “0064” of corresponding WO2014/17669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, and F780 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound in which, in a case where heat is applied to a molecular structure which has a functional group having a fluorine atom, the functional group having a fluorine atom is cut and a fluorine atom is volatilized can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

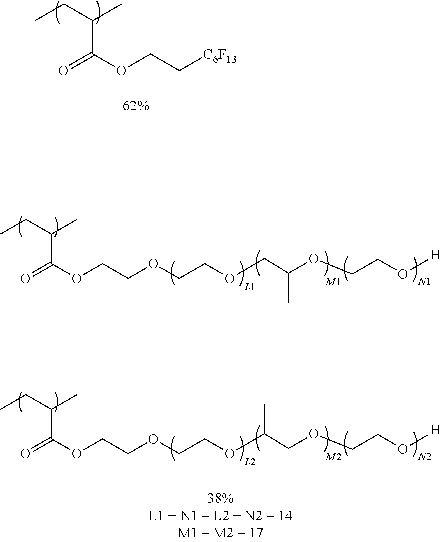

The weight-average molecular weight of the compound is preferably 3,000 to 50,000 and, for example, 14,000. In the compound, “%” representing the proportion of a repeating unit is mass %.

In addition, as the fluorine surfactant, a fluorine-containing polymer having an ethylenically unsaturated group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrication Technology Inc.), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

The content of the surfactant is preferably 0.001 mass % to 5.0 mass % and more preferably 0.005 to 3.0 mass % with respect to the total solid content of the curable composition according to the embodiment of the present invention. As the surfactant, one kind may be used alone, or two or more kinds may be used. In a case where two or more surfactants are used in combination, it is preferable that the total content of the two or more surfactants is in the above-described range.

<<Ultraviolet Absorber>>

The curable composition according to the embodiment of the present invention may include an ultraviolet absorber. As the ultraviolet absorber, for example, a conjugated diene compound, an aminobutadiene compound, a methyldibenzoyl compound, a coumarin compound, a salicylate compound, a benzophenone compound, a benzotriazole compound, an acrylonitrile compound, or a hydroxyphenyltriazine compound can be used. The details can be found in paragraphs “0052” to “0072” of JP2012-208374A and paragraphs “0317” to “0334” of JP2013-068814A, the contents of which are incorporated herein by reference. Examples of a commercially available product of the conjugated diene compound include UV-503 (manufactured by Daito Chemical Co., Ltd.). In addition, as the benzotriazole compound, MYUA series (manufactured by Miyoshi Oil&Fat Co., Ltd.; The Chemical Daily, Feb. 1, 2016) may be used.

The content of the ultraviolet absorber is preferably 0.01 to 10 mass % and more preferably 0.01 to 5 mass % with respect to the total solid content of the curable composition. In the present invention, as the ultraviolet absorber, one kind may be used alone, or two or more kinds may be used. In a case where two or ultraviolet absorbers are used in combination, it is preferable that the total content of the two or more ultraviolet absorbers is in the above-described range.

<<Other Components>>

Optionally, the curable composition according to the embodiment of the present invention may further include a sensitizer, a curing accelerator, a filler, a thermal curing accelerator, a thermal polymerization inhibitor, a plasticizer, an adhesion accelerator, and other auxiliary agents (for example, conductive particles, a filler, an antifoaming agent, a flame retardant, a leveling agent, a peeling accelerator, an antioxidant, an aromatic chemical, a surface tension adjuster, or a chain transfer agent). The details of these components can be found in paragraphs “0101” to “0104” and “0107” to “0109” of JP2008-250074A, the content of which is incorporated herein by reference. In addition, examples of the antioxidant include a phenol compound, a phosphite compound, and a thioether compound. As the antioxidant, a phenol compound having a molecular weight of 500 or higher, a phosphite compound having a molecular weight of 500 or higher, or a thioether compound having a molecular weight of 500 or higher is more preferable. Among these compounds, a mixture of two or more kinds may be used. As the phenol compound, any phenol compound which is known as a phenol antioxidant can be used. As the phenol compound, for example, a hindered phenol compound is preferable. In particular, a compound having a substituent at a position (ortho-position) adjacent to a phenolic hydroxyl group is preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include at least one compound selected from the group consisting of tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. These antioxidants are available as a commercially available product. Examples of the commercially available product include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by Adeka Corporation). The content of the antioxidant is preferably 0.01 to 20 mass % and more preferably 0.3 to 15 mass % with respect to the mass of the total solid content of the curable composition. As the antioxidant, one kind may be used alone, or two or more kinds may be used. In a case where two or more antioxidants are used in combination, it is preferable that the total content of the two or more antioxidants is in the above-described range.

For example, in a case where a film is formed by coating, the viscosity (23° C.) of the curable composition according to the embodiment of the present invention is preferably 1 to 100 mPa·s. The lower limit is more preferably 2 mPa·s or higher and still more preferably 3 mPa·s or higher. The upper limit is more preferably 50 mPa·s or lower, still more preferably 30 mPa·s or lower, and still more preferably 15 mPa·s or lower.

A storage container of the curable composition according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

The use of the curable composition according to the embodiment of the present invention is not particularly limited. The composition according to the embodiment of the present invention can be preferably used to form a near infrared cut filter or the like. In addition, by the curable composition according to the embodiment of the present invention including the coloring material that shields visible light, an infrared transmitting filter that can allow transmission of only near infrared light at a specific wavelength or higher can also be formed.

<Method of Preparing Curable Composition>

The curable composition according to the embodiment of the present invention can be prepared by mixing the above-described components with each other. During the preparation of the curable composition, all the components may be dissolved or dispersed in a solvent at the same time to prepare the curable composition. Optionally, two or more solutions or dispersions to which the respective components are appropriately added may be prepared, and the solutions or dispersions may be mixed with each other during use (during application) to prepare the curable composition.

In addition, in a case where the curable composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that rough particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the curable composition, it is preferable that the curable composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd.

In a case where a filter is used, a combination of different filters (for example, a first filter and a second filter) may be used. At this time, the filtering using each of the filters may be performed once, or twice or more.

In addition, a combination of filters having different pore sizes in the above-described range may be used. Here, the pore size of the filter can refer to a nominal value of a manufacturer of the filter. A commercially available filter can be selected from various filters manufactured by Pall Corporation (for example, DFA4201NXEY), Toyo Roshi Kaisha, Ltd., Entegris Japan Co., Ltd. (former Mykrolis Corporation), or Kits Microfilter Corporation.

The second filter may be formed of the same material as that of the first filter.

In addition, the filtering using the first filter may be performed only on the dispersion, and the filtering using the second filter may be performed on a mixture of the dispersion and other components.

<Cured Film>

The cured film according to the embodiment of the present invention is obtained from the above-described curable composition according to the embodiment of the present invention. The cured film according to the present invention can be preferably used as a near infrared cut filter. In addition, the cured film according to the embodiment of the present invention can also be used as a heat ray shielding filter or an infrared transmitting filter. The cured film according to the embodiment of the present invention may be used in a state where it is laminated on a support, or may be peeled off from a support. The cured film according to the present invention may be a film having a pattern or a film (flat film) not having a pattern. In a case where the cured film according to the embodiment of the present invention is used as an infrared transmitting filter, examples of the infrared transmitting filter include a filter that shields visible light and allows transmission of light in a wavelength range of 900 nm or longer. In a case where the cured film according to the embodiment of the present invention is used as an infrared transmitting filter, the near infrared absorbing colorant has a function of limiting light to be transmitted (near infrared light) to a long wavelength side.

The thickness of the cured film according to the embodiment of the present invention can be appropriately adjusted according to the purpose. The thickness of the cured film is preferably 20 μm or less, more preferably 10 μm or less, and still more preferably 5 μm or less. For example, the lower limit of the thickness is preferably 0.1 μm or more, more preferably 0.2 μm or more, and still more preferably 0.3 μm or more.

The cured film according to the embodiment of the present invention has a maximum absorption wavelength preferably in a wavelength range of 700 to 1000 nm, more preferably in a wavelength range of 720 to 980 nm, and more preferably in a wavelength range of 740 to 960 nm.

In a case where the cured film according to the embodiment of the present invention is used as a near infrared cut filter, it is preferable that the cured film according to the embodiment of the present invention satisfies at least one of the following condition (1), . . . , or (4), and it is more preferable that the film according to the embodiment of the present invention satisfies all the following conditions (1) to (4).

(1) A transmittance at a wavelength of 400 nm is preferably 70% or higher, more preferably 80% or higher, still more preferably 85% or higher, and still more preferably 90% or higher

(2) A transmittance at a wavelength of 500 nm is preferably 70% or higher, more preferably 80% or higher, still more preferably 90% or higher, and still more preferably 95% or higher

(3) A transmittance at a wavelength of 600 nm is preferably 70% or higher, more preferably 80% or higher, still more preferably 90% or higher, and still more preferably 95% or higher

(4) A transmittance at a wavelength of 650 nm is preferably 70% or higher, more preferably 80% or higher, still more preferably 90% or higher, and still more preferably 95% or higher

The cured film according to the embodiment of the present invention can be used in combination with a color filter that includes a chromatic colorant. The color filter can be manufactured using a coloring composition including a chromatic colorant. Examples of the chromatic colorant include the chromatic colorants which may be included in the curable composition according to the embodiment of the present invention. In addition, the cured film according to the embodiment of the present invention may be used as a filter having not only a function as a near infrared cut filter but also a function as a color filter by including a chromatic colorant.

In a case where the cured film according to the embodiment of the present invention is used in combination with a color filter, it is preferable that the color filter is disposed on an optical path of the cured film according to the embodiment of the present invention. For example, the cured film according to the embodiment of the present invention and the color filter can be laminated to be used as a laminate. In the laminate, the cured film according to the embodiment of the present invention and the color filter may be or may not be adjacent to each other in a thickness direction. In a case where the cured film according to the embodiment of the present invention is not adjacent to the color filter in the thickness direction, the cured film according to the embodiment of the present invention may be formed on another support other than a support on which the color filter is formed, or another member (for example, a microlens or a planarizing layer) constituting a solid image pickup element may be interposed between the cured film according to the embodiment of the present invention and the color filter.

In the present invention, “near infrared cut filter” refers to a filter that allows transmission of light (visible light) in the visible range and shields at least a part of light (near infrared light) in the near infrared range. The near infrared cut filter may be a filter that allows transmission of light in the entire wavelength range of the visible range, or may be a filter that allows transmission of light in a specific wavelength range of the visible range and shields light in another specific wavelength range of the visible range. In addition, in the present invention, a color filter refers to a filter that allows transmission of light in a specific wavelength range of the visible range and shields light in another specific wavelength range of the visible range. In addition, in the present invention, “infrared transmitting filter” refers to a filter that shields visible light and allows transmission of at least a part of near infrared light.

The cured film according to the embodiment of the present invention can be used in various devices including a solid image pickup element such as a charge coupled device (CCD) or a complementary metal-oxide semiconductor (CMOS), an infrared sensor, or an image display device.

<Method of Forming Cured Film>

Next, a method of forming the cured film according to the embodiment of the present invention will be described. The cured film according to the embodiment of the present invention can be formed through a step of applying the curable composition according to the embodiment of the present invention to a support.

In the method of forming the cured film, it is preferable that the curable composition is applied to a support. Examples of the support include a substrate formed of a material such as silicon, non-alkali glass, soda glass, PYREX (registered trade name) glass, or quartz glass. For example, an organic film or an inorganic film may be formed on the substrate. Examples of a material of the organic film include the above-described resin. In addition, as the support, a substrate formed of the above-described resin can also be used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat. In addition, in a case where a glass substrate is used as the support, it is preferable that an inorganic film is formed on the glass substrate or the glass substrate may be dealkalized to be used. According to this aspect, a film in which the occurrence of foreign matter is suppressed can be easily formed.

As a method of applying the curable composition, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent-” (February, 2005, S.B. Research Co., Ltd.) and methods described in JP2003-262716A, JP2003-185831A, JP2003-261827A, JP2012-126830A, and JP2006-169325A.

A composition layer formed by applying the curable composition may be dried (pre-baked). In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. By setting the pre-baking temperature to be 150° C. or lower, the characteristics can be effectively maintained, for example, even in a case where a photoelectric conversion film of an image sensor is formed of an organic material.

The pre-baking time is preferably 10 to 3000 seconds, more preferably 40 to 2500 seconds, and still more preferably 80 to 220 seconds. Drying can be performed using a hot plate, an oven, or the like.

The method of forming the cured film according to the embodiment of the present invention may further include a step of forming a pattern. Examples of a pattern forming method include a pattern forming method using a photolithography method and a pattern forming method using a dry etching method. In a case where the cured film according to the embodiment of the present invention is used as a flat film, the step of forming a pattern is not necessarily performed. Hereinafter, the step of forming a pattern will be described in detail.

(Case where Pattern is Formed Using Photolithography Method)

It is preferable that the pattern forming method using a photolithography method includes: a step (exposure step) of exposing the composition layer, which is formed by applying the curable composition according to the embodiment of the present invention, in a pattern shape; and a step (development step) of forming a pattern by removing a non-exposed portion of the composition layer for development. Optionally, the pattern forming method may further include a step (post-baking step) of baking the developed pattern. Hereinafter, the respective steps will be described.

<<Exposure Step>>

In the exposure step, the composition layer is exposed in a pattern shape. For example, the composition layer can be exposed in a pattern shape using an exposure device such as a stepper through a mask having a predetermined mask pattern. As a result, an exposed portion can be cured. As radiation (light) used during the exposure, ultraviolet rays such as g-rays or i-rays are preferable, and i-rays are more preferable. For example, the irradiation dose (exposure dose) is preferably 0.03 to 2.5 J/cm², more preferably 0.05 to 1.0 J/cm², and most preferably 0.08 to 0.5 J/cm². The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %). In addition, the exposure illuminance can be appropriately set and typically can be selected in a range of 1000 W/m² to 100000 W/m² (for example, 5000 W/m², 15000 W/m², or 35000 W/m²). Conditions of the oxygen concentration and conditions of the exposure illuminance may be appropriately combined. For example, conditions are oxygen concentration: 10 vol % and illuminance: 10000 W/m², or oxygen concentration: 35 vol % and illuminance: 20000 W/m².

<<Development Step>>

Next, a pattern is formed by removing a non-exposed portion of the exposed composition layer by development. The non-exposed portion of the composition layer can be removed by development using a developer. As a result, a non-exposed portion of the composition layer in the exposure step is eluted into the developer, and only the photocured portion remains on the support. As the developer, an alkali developer which does not cause damages to a solid image pickup element as an underlayer, a circuit or the like is desired. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

Examples of the alkaline agent used as the developer include: an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. As the developer, an alkaline aqueous solution in which the above alkaline agent is diluted with pure water is preferably used. A concentration of the alkaline agent in the alkaline aqueous solution is preferably 0.001 to 10 mass % and more preferably 0.01 to 1 mass %. In addition, a surfactant may be used as the developer. Examples of the surfactant include the above-described surfactants. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where a developer including the alkaline aqueous solution is used, it is preferable that the layer is rinsed with pure water after development.

After the development, the film can also be dried and then heated (post-baking). Post-baking is a heat treatment which is performed after development to completely cure the film. In a case where post-baking is performed, for example, the post-baking temperature is preferably 100° C. to 240° C. From the viewpoint of curing the film, the post-baking temperature is more preferably 200° C. to 230° C. In addition, in a case where an organic electroluminescence (organic EL) element is used as a light-emitting light source, or in a case where a photoelectric conversion film of an image sensor is formed of an organic material, the post-baking temperature is preferably 150° C. or lower, more preferably 120° C. or lower, still more preferably 100° C. or lower, and still more preferably 90° C. or lower. The lower limit is, for example, 50° C. or higher. The film after the development is post-baked continuously or batchwise using heating means such as a hot plate, a convection oven (hot air circulation dryer), or a high-frequency heater under the above-described conditions. In addition, in a case where a pattern is formed through a low-temperature process, post-baking is not necessarily performed.

(Case where Pattern is Formed Using Dry Etching Method)

The formation of a pattern using a dry etching method can be performed using a method including: applying the curable composition according to the embodiment of the present invention to a support or the like to form a composition layer; curing the composition layer to form a cured composition layer; forming a patterned photoresist layer on the cured composition layer; and dry-etching the cured composition layer with etching gas by using the patterned photoresist layer as a mask. It is preferable that pre-baking is further performed in order to form the photoresist layer. The details of the pattern formation using the dry etching method can be found in paragraphs “0010” to “0067” of JP2013-064993A, the content of which is incorporated herein by reference.

<Near Infrared Cut Filter>

In addition, a near infrared cut filter according to the embodiment of the present invention will be described. The near infrared cut filter according to the embodiment of the present invention includes the cured film according to the embodiment of the present invention.

The near infrared cut filter according to the embodiment of the present invention may further include, for example, a layer containing copper, a dielectric multi-layer film, or an ultraviolet absorbing layer in addition to the cured film according to the embodiment of the present invention. By further including the layer containing copper and/or the dielectric multi-layer film, the near infrared cut filter having a viewing angle and excellent infrared shielding properties can be easily obtained. In addition, by including the ultraviolet absorbing layer, the near infrared cut filter having excellent ultraviolet shielding properties can be obtained. The details of the ultraviolet absorbing layer can be found in, for example, the description of an absorbing layer described in paragraphs “0040” to “0070” and paragraphs “0119” to “0145” of WO2015/099060A, the content of which is incorporated herein by reference. The details of the dielectric multi-layer film can be found in paragraphs “0255” to “0259” of JP2014-041318A, the content of which is incorporated herein by reference. As the layer containing copper, a glass substrate (copper-containing glass substrate) formed of glass containing copper, or a layer (copper complex-containing layer) containing a copper complex may also be used. Examples of the copper-containing glass substrate include a phosphate glass including copper and a fluorophosphate glass including copper. Examples of a commercially available product of the copper-containing glass include NF-50 (manufactured by AGC Techno Glass Co., Ltd.), BG-60 and BG-61 (both of which are manufactured by Schott AG), and CD5000 (manufactured by Hoya Corporation).

The near infrared cut filter according to the embodiment of the present invention can be used in various devices including a solid image pickup element such as a charge coupled device (CCD) or a complementary metal-oxide semiconductor (CMOS), an infrared sensor, or an image display device.

<Solid Image Pickup Element>

A solid image pickup element according to the embodiment of the present invention includes the cured film according to the embodiment of the present invention. The configuration of the solid image pickup element according to the embodiment of the present invention is not particularly limited as long as it includes the cured film according to the embodiment of the present invention and functions as a solid image pickup element. For example, the following configuration can be adopted.

The solid image pickup element includes a plurality of photodiodes and transfer electrodes on the support, the photodiodes constituting a light receiving area of the solid image pickup element, and the transfer electrode being formed of polysilicon or the like. In the solid image pickup element, a light shielding film formed of tungsten or the like which has openings through only light receiving sections of the photodiodes is provided on the photodiodes and the transfer electrodes, a device protective film formed of silicon nitride or the like is formed on the light shielding film so as to cover the entire surface of the light shielding film and the light receiving sections of the photodiodes, and the cured film according to the embodiment of the present invention is formed on the device protective film. Further, a configuration in which light collecting means (for example, a microlens; hereinafter, the same shall be applied) is provided above the device protective film and below the cured film according to the embodiment of the present invention (on a side thereof close the support), or a configuration in which light collecting means is provided on the cured film according to the embodiment of the present invention may be adopted. In addition, the color filter may have a structure in which a film which forms each pixel is embedded in a space which is partitioned in, for example, a lattice shape by a partition wall. In this case, it is preferable that the partition wall has a lower refractive index than each pixel. Examples of an imaging device having such a structure include a device described in JP2012-227478A and JP2014-179577A.

<Image Display Device>

An image display device according to the embodiment of the present invention includes the cured film according to the embodiment of the present invention. Examples of the image display device include a liquid crystal display device or an organic electroluminescence (organic EL) display device. The definition and details of the image display device can be found in, for example, “Electronic Display Device (by Akiya Sasaki, Kogyo Chosakai Publishing Co., Ltd., 1990)” or “Display Device (Sumiaki Ibuki, Sangyo Tosho Co., Ltd.). In addition, the details of a liquid crystal display device can be found in, for example, “Next-Generation Liquid Crystal Display Techniques (Edited by Tatsuo Uchida, Kogyo Chosakai Publishing Co., Ltd., 1994)”. The liquid crystal display device to which the present invention is applicable is not particularly limited. For example, the present invention is applicable to various liquid crystal display devices described in “Next-Generation Liquid Crystal Display Techniques”. The image display device may include a white organic EL element. It is preferable that the white organic EL element has a tandem structure. The tandem structure of the organic EL element is described in, for example, JP2003-045676A, or pp. 326-328 of “Forefront of Organic EL Technology Development—Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

<Infrared Sensor>

An infrared sensor according to the embodiment of the present invention includes the cured film according to the embodiment of the present invention. The configuration of the infrared sensor is not particularly limited as long as it functions as an infrared sensor. Hereinafter, an embodiment of the infrared sensor used in the present invention will be described using the drawings.

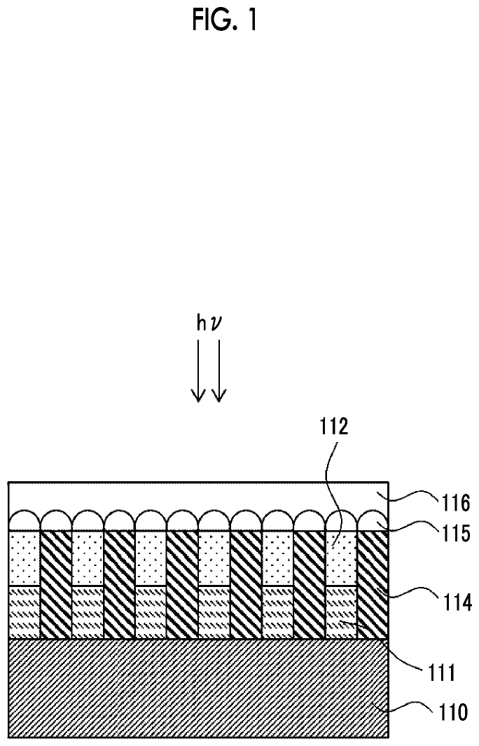

In FIG. 1, reference numeral 110 represents a solid image pickup element. In an imaging region provided on a solid image pickup element 110, near infrared cut filters 111 and infrared transmitting filters 114 are provided. In addition, color filters 112 are laminated on the near infrared cut filters 111. Microlenses 115 are disposed on an incidence ray hυ side of the color filters 112 and the infrared transmitting filters 114. A planarizing layer 116 is formed so as to cover the microlenses 115.

The near infrared cut filter 111 can be formed using the curable composition according to the embodiment of the present invention. Spectral characteristics of the near infrared cut filters 111 can be selected according to the emission wavelength of an infrared light emitting diode (infrared LED) to be used.

The color filters 112 is not particularly limited as long as pixels which allow transmission of light having a specific wavelength in the visible range and absorbs the light are formed therein, and well-known color filters of the related art for forming a pixel can be used. For example, pixels of red (R), green (G), and blue (B) are formed in the color filters. For example, the details of the color filters can be found in paragraphs “0214” to “0263” of JP2014-043556A, the content of which is incorporated herein by reference.

Characteristics of the infrared transmitting filters 114 can be selected according to the emission wavelength of the infrared LED to be used. For example, in a case where the emission wavelength of the infrared LED is 850 nm, a maximum value of a light transmittance of the infrared transmitting filter 114 in the thickness direction of the film in a wavelength range of 400 to 650 nm is preferably 30% or lower, more preferably 20% or lower, still more preferably 10% or lower and still more preferably 0.1% or lower. It is preferable that the light transmittance of the infrared transmitting filter in the thickness direction satisfies the above-described conditions in the entire wavelength range of 400 to 650 nm.

A minimum value of a light transmittance of the infrared transmitting filter 114 in the thickness direction of the film in a wavelength range of 800 nm or longer (preferably 800 to 1300 nm) is preferably 70% or higher, more preferably 80% or higher, and still more preferably 90% or higher. It is preferable that the transmittance satisfies the above-described conditions in a part of a wavelength range of 800 nm or longer, and it is more preferable that the transmittance satisfies the above-described conditions at a wavelength corresponding to the emission wavelength of the infrared LED.

The thickness of the infrared transmitting filter 114 is preferably 100 μm or less, more preferably 15 μm or less, still more preferably 5 μm or less, and still more preferably 1 μm or less. The lower limit value is preferably 0.1 μm. In a case where the thickness is in the above-described range, the film can satisfy the above-described spectral characteristics.

A method of measuring the spectral characteristics, the thickness, and the like of the infrared transmitting filter 114 are as follows.

The thickness is obtained by measuring the thickness of the dried substrate including the film using a stylus surface profilometer (DEKTAK 150, manufactured by ULVAC Inc.).

The spectral characteristics of the film are values obtained by measuring the transmittance in a wavelength range of 300 to 1300 nm using a spectrophotometer (U-4100, manufactured by Hitachi High-Technologies Corporation).

In addition, for example, in a case where the emission wavelength of the infrared LED is 940 nm, it is preferable that a maximum value of a light transmittance of the infrared transmitting filter 114 in a thickness direction in a wavelength range of 450 to 650 nm is 20% or lower, that a light transmittance of the infrared transmitting filter 114 in the thickness direction at a wavelength of 835 nm is 20% or lower, and that a minimum value of a light transmittance of the infrared transmitting filter 114 in the thickness direction in a wavelength range of 1000 to 1300 nm is 70% or higher.

In the infrared sensor shown in FIG. 1, a near infrared cut filter (other near infrared cut filter) other than the near infrared cut filter 111 may be further disposed on the planarizing layer 116. As the other near infrared cut filter, for example, a layer containing copper and/or a dielectric multi-layer film may be provided. The details of the groups are as described above. In addition, as the other near infrared cut filter, a dual band pass filter may be used.

In addition, in the infrared sensor illustrated in FIG. 1, the position of the near infrared cut filter 111 and the position of the color filter 112 may be replaced with each other. In addition, another layer may be arranged between the solid image pickup element 110 and the near infrared cut filter 111 and/or between the solid image pickup element 110 and the infrared transmitting filter 114. Examples of the other layer include an organic layer that is formed using a composition including a polymerizable compound, a resin, and a photopolymerization initiator. In addition, a planarizing layer may be formed on the color filter 112.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”. In addition, in the following structural formulae, Me represents a methyl group, Et represents an ethyl group, Bu represents a butyl group, and Ph represents a phenyl group.

### Test Example 1

<Preparation of Composition>

Raw materials shown in the following table were mixed and stirred at a ratio (part(s) by mass) shown in the following table, and the mixture was filtered through a nylon filter (manufactured by Pall Corporation) having a pore size of 0.45 μm. As a result, each composition was prepared. In Example 16, in addition to raw material shown in the following table, 0.50 parts by mass of benzopinacol was added to prepare a composition.

TABLE 1

| | | Example | Example | Example | Example | Example | Example | Example | Example |
|---|---|---|---|---|---|---|---|---|---|
| | | 1 | 2 | 3 | 4 | 5 | 6 | 7 | 8 |
| Kind of Near Infrared | | Al | A1/A2 | A3 | A4 | A3 | A3 | A3 | A3 |
| Absorbing Colorant | | | | | | | | | |
| Content of Near Infrared | | 4.81 | 1.20/3.61 | 4.81 | 4.81 | 4.81 | 4.81 | 4.81 | 4.81 |
| Absorbing Colorant | | | | | | | | | |
| Dispersion 1 | | — | — | — | — | — | — | — | |
| Dispersion 2 | | — | — | — | — | — | — | — | — |
| Resin | 1 | 27.89 | 27.89 | 27.89 | 27.89 | 27.89 | 27.89 | 27.89 | 27.89 |
| | 2 | — | — | — | — | — | — | — | — |
| | 3 | — | — | — | — | — | — | — | — |
| Polymerizable | 1 | 2.00 | 2.00 | 2.00 | 2.00 | 2.00 | 2.00 | 2.00 | 2.40 |
| Compound | | | | | | | | | |
| Photopolymerization | 1 | 2.17 | 2.17 | 2.17 | 2.17 | — | — | — | — |
| Initiator | 2 | — | — | — | — | 2.17 | — | — | — |
| | 3 | — | — | — | — | — | 2.17 | — | — |
| | 4 | — | — | — | — | — | — | 2.17 | — |
| | 5 | — | — | — | — | — | — | — | 2.17 |
| | 6 | — | — | — | — | — | — | — | — |
| | 7 | — | — | — | — | — | — | — | — |
| | 8 | — | — | — | — | — | — | — | — |
| | 9 | — | — | — | — | — | — | — | — |
| | 10 | — | — | — | — | — | — | — | — |
| | 11 | — | — | — | — | — | — | — | — |
| | 12 | — | — | — | — | — | — | — | — |
| | 13 | — | — | — | — | — | — | — | — |

| | | | | | | | | |
|---|---|---|---|---|---|---|---|---|
| Surfactant 1 | 2.28 | 2.28 | 2.28 | 2.28 | 2.28 | 2.28 | 0.39 | 0.04 |
| Polymerization Inhibitor | 0.001 | 0.001 | 0.001 | 0.001 | 0.001 | 0.001 | 0.001 | 0.001 |
| Solvent 1 | 58.00 | 58.00 | 58.00 | 58.00 | 58.00 | 58.00 | 55.54 | 55.54 |

TABLE 2

| | | Example | Example | Example | Example | Example | Example | Example | Example |
|---|---|---|---|---|---|---|---|---|---|
| | | 9 | 10 | 11 | 12 | 13 | 14 | 15 | 16 |
| Kind of Near Infrared | | A3 | A3 | A3 | A4 | A4 | A4 | A4 | A4 |
| Absorbing Colorant | | | | | | | | | |
| Content of Near Infrared | | 4.81 | 4.81 | 4.81 | 4.81 | 4.81 | 4.81 | 4.81 | 4.81 |
| Absorbing Colorant | | | | | | | | | |
| Dispersion 1 | | — | — | — | — | — | — | — | — |
| Dispersion 2 | | — | — | — | — | — | — | — | — |
| Resin | 1 | 27.89 | 27.89 | 27.89 | 27.89 | 27.89 | 27.89 | 27.89 | 27.89 |
| | 2 | — | — | — | — | — | — | — | — |
| | 3 | — | — | — | — | — | — | — | — |
| Polymerizable | 1 | 2.00 | 2.40 | 2.00 | 2.00 | 2.00 | 2.00 | 2.40 | 2.00 |
| Compound | | | | | | | | | |
| Photopolymerization | 1 | — | — | — | — | — | — | — | — |
| Initiator | 2 | — | — | — | 2.17 | — | — | — | — |
| | 3 | — | — | — | — | 2.17 | — | — | — |
| | 4 | — | — | — | — | — | 2.17 | — | — |
| | 5 | — | — | — | — | — | — | 2.17 | — |
| | 6 | 2.17 | — | — | — | — | — | — | 2.17 |
| | 7 | — | 2.17 | — | — | — | — | — | — |
| | 8 | — | — | 2.17 | — | — | — | — | — |
| | 9 | — | — | — | — | — | — | — | — |
| | 10 | — | — | — | — | — | — | — | — |
| | 11 | — | — | — | — | — | — | — | — |
| | 12 | — | — | — | — | — | — | — | — |
| | 13 | — | — | — | — | — | — | — | — |

| | | | | | | | | |
|---|---|---|---|---|---|---|---|---|
| Surfactant 1 | 2.28 | 0.04 | 2.28 | 2.28 | 2.28 | 0.39 | 0.04 | 2.28 |
| Polymerization Inhibitor | 0.001 | 0.001 | 0.001 | 0.001 | 0.001 | 0.001 | 0.001 | 0.001 |
| Solvent 1 | 58.00 | 55.54 | 58.00 | 58.00 | 58.00 | 55.54 | 55.54 | 58.00 |

TABLE 3

| | | Example | Example | Example | Example | Example | Example | Example | Example |
|---|---|---|---|---|---|---|---|---|---|
| | | 17 | 18 | 19 | 20 | 21 | 22 | 23 | 24 |
| Kind of Near Infrared | | A4 | A4 | A4/A3 | A1/A3 | A1/A4 | A1/A4/A3 | A5 | A6 |
| Absorbing Colorant | | | | | | | | | |
| Content of Near Infrared | | 4.81 | 4.81 | 2.40/2.41 | 2.40/2.41 | 2.40/2.41 | 1.60/1.60/1.61 | 4.81 | 4.81 |
| Absorbing Colorant | | | | | | | | | |
| Dispersion 1 | | — | — | — | — | — | — | — | — |
| Dispersion 2 | | — | — | — | — | — | — | — | — |
| Resin | 1 | 27.89 | 27.89 | 27.89 | 27.89 | 27.89 | 27.89 | 27.89 | 2789 |
| | 2 | — | — | — | — | — | — | — | — |
| | 3 | — | — | — | — | — | — | — | — |
| Polymerizable | 1 | 2.40 | 2.00 | 2.00 | 2.00 | 2.00 | 2.00 | 2.00 | 2.00 |
| Compound | | | | | | | | | |
| Photopolymerization | 1 | — | — | 2.17 | 2.17 | 2.17 | 2.17 | 2.17 | 2.17 |
| Initiator | 2 | — | — | — | — | — | — | — | — |
| | 3 | — | — | — | — | — | — | — | — |
| | 4 | — | — | — | — | — | — | — | — |
| | 5 | — | — | — | — | — | — | — | — |
| | 6 | — | — | — | — | — | — | — | — |
| | 7 | 2.17 | — | — | — | — | — | — | — |
| | 8 | — | 2.17 | — | — | — | — | — | — |
| | 9 | — | — | — | — | — | — | — | — |
| | 10 | — | — | — | — | — | — | — | — |
| | 11 | — | — | — | — | — | — | — | — |
| | 12 | — | — | — | — | — | — | — | — |
| | 13 | — | — | — | — | — | — | — | — |

| | | | | | | | | |
|---|---|---|---|---|---|---|---|---|
| Surfactant 1 | 0.04 | 2.28 | 2.28 | 2.28 | 2.28 | 2.28 | 2.28 | 2.28 |
| Polymerization Inhibitor | 0.001 | 0.001 | 0.001 | 0.001 | 0.001 | 0.001 | 0.001 | 0.001 |
| Solvent 1 | 55.54 | 58.00 | 58.00 | 58.00 | 58.00 | 58.00 | 58.00 | 58.00 |

TABLE 4

| | | Example | Example | Example | Example | Comparative | Comparative | Comparative | Comparative | Comparative |
|---|---|---|---|---|---|---|---|---|---|---|
| | | 25 | 26 | 27 | 28 | Example 1 | Example 2 | Example 3 | Example 4 | Example 5 |
| Kind of Near Infrared | | A9 | A1 | A7 | A7/A8 | A5 | A5 | A5 | A5 | A6 |
| Absorbing Colorant | | | | | | | | | | |
| Content of Near Infrared | | 4.81 | 4.00 | 1.00 | 3.61/1.21 | 4.81 | 4.81 | 4.81 | 4.81 | 4.81 |
| Absorbing Colorant | | | | | | | | | | |
| Dispersion1 | | — | 5.36 | — | — | — | — | — | — | — |
| Dispersion 2 | | — | — | 8.36 | — | — | — | — | — | — |
| Resin | 1 | — | 27.89 | 27.89 | — | 27.89 | 27.89 | 27.89 | 27.89 | 27.89 |
| | 2 | 27.89 | — | — | — | — | — | — | — | — |
| | 3 | — | — | — | 27.89 | — | — | — | — | — |
| Polymerizable | 1 | 2.00 | 2.00 | 2.00 | 2.00 | 2.00 | 2.00 | 2.00 | 2.00 | 2.00 |
| Compound | | | | | | | | | | |
| Photopolymerization | 1 | 2.17 | 2.17 | 2.17 | 2.17 | — | — | — | — | — |
| Initiator | 2 | — | — | — | — | — | — | — | — | — |
| | 3 | — | — | — | — | — | — | — | — | — |
| | 4 | — | — | — | — | — | — | — | — | — |
| | 5 | — | — | — | — | — | — | — | — | — |
| | 6 | — | — | — | — | — | — | — | — | — |
| | 7 | — | — | — | — | — | — | — | — | — |
| | 8 | — | — | — | — | — | — | — | — | — |
| | 9 | — | — | — | — | 2.17 | — | — | — | — |
| | 10 | — | — | — | — | — | 2.17 | — | — | — |
| | 11 | — | — | — | — | — | — | 2.17 | — | — |
| | 12 | — | — | — | — | — | — | — | 2.17 | — |
| | 13 | — | — | — | — | — | — | — | — | 2.17 |

| | | | | | | | | | |
|---|---|---|---|---|---|---|---|---|---|
| Surfactant 1 | 2.28 | 2.28 | 2.28 | 2.28 | 2.28 | 2.28 | 2.28 | 2.28 | 2.28 |
| Polymerization Inhibitor | 0.001 | 0.001 | 0.001 | 0.001 | 0.001 | 0.001 | 0.001 | 0.001 | 0.001 |
| Solvent 1 | 60.80 | 58.00 | 58.00 | 58.00 | 55.00 | 55.00 | 55.00 | 55.00 | 55.00 |

The raw materials shown above in the table are as follows.

(Near Infrared Absorbing Colorant)
A1 to A8: compounds having the following structures.
A9: NK-5060 (manufactured by Hayashibara Co., Ltd., Cyanine Compound)

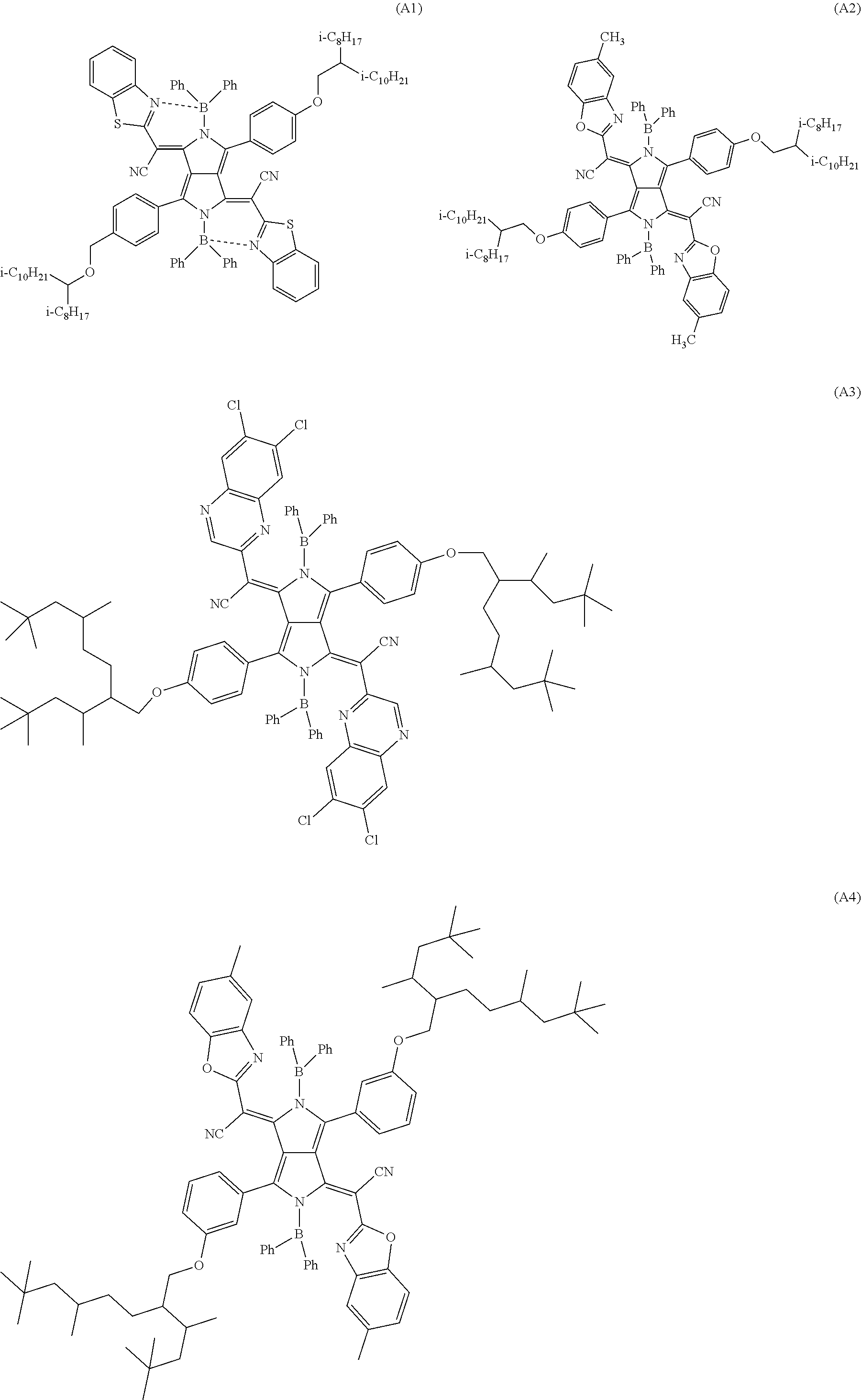

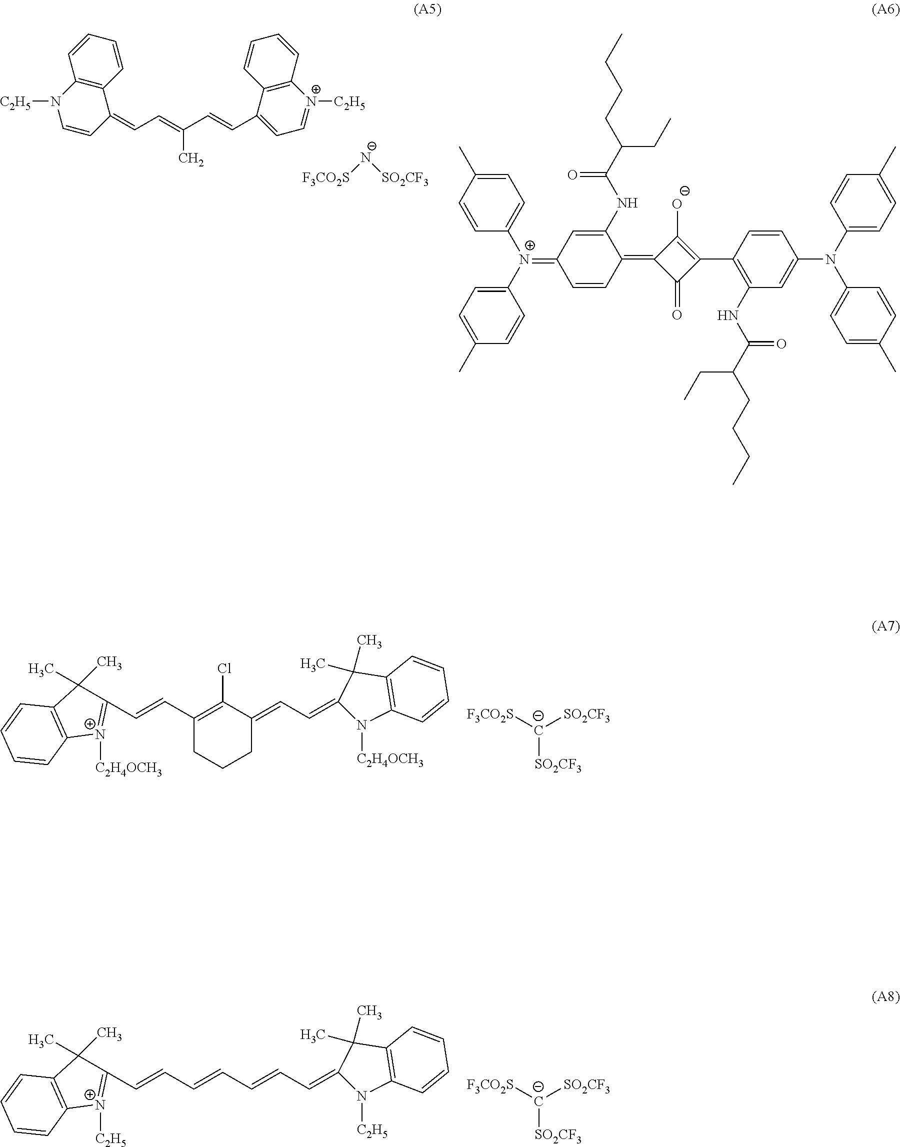

(Resin)
Resin 1: a cyclopentanone 30 mass % solution of a resin having the following structure (weight-average molecular weight: 41,400; a numerical value added to a repeating unit represents a mol number)

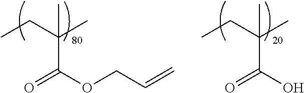

Resin 2: a cyclohexanone 30 mass % solution of ARTON F4520 (manufactured by JSR Corporation)
Resin 3: a cyclohexanone 30 mass % solution of a random polymer having a glycidyl methacrylate skeleton (MARPROOF G-0150M, manufactured by NOF Corporation, weight-average molecular weight: 10,000)

(Solvent)
Solvent 1: cyclopentanone

(Polymerization Inhibitor)
Polymerization Inhibitor: p-methoxyphenol

(Polymerizable Compound)

Polymerizable Compound 1: a mixture of the following compounds (a mixture in which a molar ratio between a left compound and a right compound is 7:3)

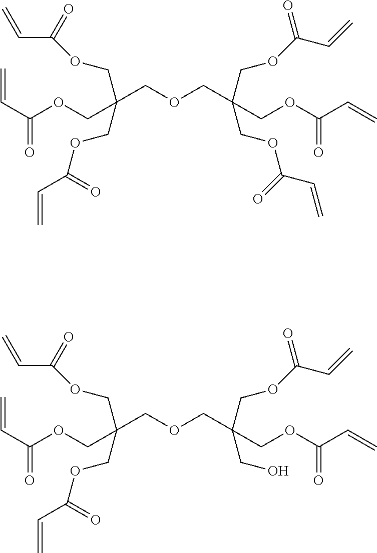 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

(Photopolymerization Initiator)
Photopolymerization initiator 1: IRGACURE-379 (manufactured by BASF SE, an α-aminoalkylphenone compound)
Photopolymerization initiator 2: IRGACURE-819 (manufactured by BASF SE, an acylphosphine oxide compound)
Photopolymerization initiator 3: IRGACURE-TPO (manufactured by BASF SE, an acylphosphine oxide compound)
Photopolymerization initiator 4: IRGACURE-369 (manufactured by BASF SE, an α-aminoalkylphenone compound)
Photopolymerization initiator 5: IRGACURE-651 (manufactured by BASF SE, a benzyldimethylketal compound)
Photopolymerization initiator 6: IRGACURE-184 (manufactured by BASF SE, an α-hydroxyalkylphenone compound)
Photopolymerization initiator 7: B-CIM (manufactured by Hodogaya Chemical Co., Ltd., a biimidazole compound)
Photopolymerization initiator 8: TRIAZINE PP (manufactured by Nihon Siber Hegner K. K., a triazine compound)
Photopolymerization initiator 9: IRGACURE-OXE01 (manufactured by BASF SE, an oxime compound)
Photopolymerization initiator 10: IRGACURE-OXE02 (manufactured by BASF SE, an oxime compound)
Photopolymerization initiator 11: IRGACURE-OXE03 (manufactured by BASF SE, an oxime compound)
Photopolymerization initiator 12: ADEKA ARKLS NCI-831 (manufactured by Adeka Corporation, an oxime compound)
Photopolymerization initiator 13: ADEKA ARKLS NCI-931 (manufactured by Adeka Corporation, an oxime compound)

(Surfactant)
Surfactant 1: a polymer including a repeating unit represented by Formula the following Formula (B1-1) and a repeating unit represented by the following Formula (B3-1) (weight-average molecular weight=7,400 g/mol; B1-1:B3−1=92.5:7.5 (molar ratio)). In the following Formula (B3-1), X represents a perfluoromethylene group or a perfluoroethylene group, and r represents the number of repeating units. Regarding X, a ratio —CF₂—CF₂—:—CF₂—:—CH₂—CF₂— between the number of —CF₂—CF₂—, the number of —CF₂—, and the number of —CH₂—CF₂— was 4.2:1.9:1.0.

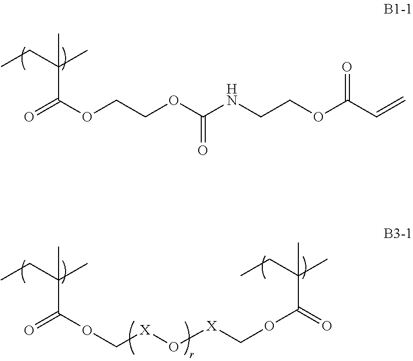

(Dispersion 1)

Raw materials having the following composition were dispersed for 2 hours using a beads mill (a high-pressure disperser with a pressure reducing mechanism, NANO-3000-10 (manufactured by Nippon BEE Chemical Co., Ltd.)) with zirconia beads having a diameter of 0.3 mm. As a result, a dispersion 1 was prepared.

—Composition of Dispersion 1—

| | |
|---|---|
| Near infrared absorbing colorant having the following structure (average primary particle size: 200 nm) | 11.6 parts by mass |
| 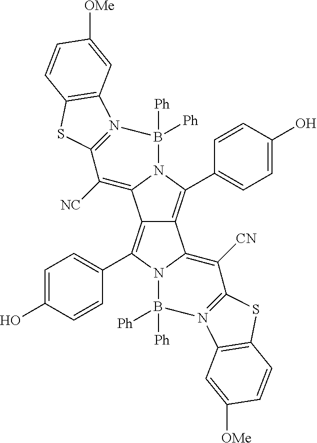 | |
| Pigment derivative having the following structure | 3.5 parts by mass |
| 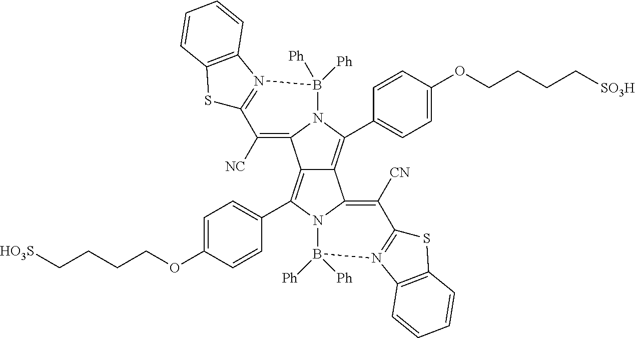 | |
| Dispersant (a resin having the following structure; weight-average molecular weight: 22,900; a numerical value added to a | 7.2 parts by mass |
| repeating unit at a main chain represents a mol number, and a numerical value added to a repeating unit at a side chain | |
| represents the number of the repeating units) | |
| 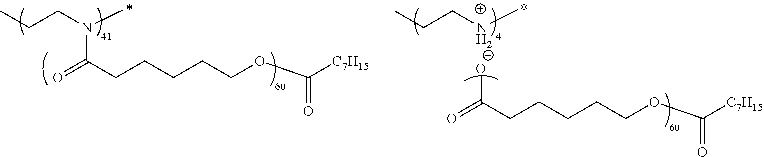 | |
| 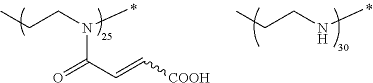 | |
| Cyclohexanone | 77.77 parts by mass |

(Dispersion 2)

60 parts by mass of C.I. Pigment Black 32, 20 parts by mass of C.I. Pigment Blue 15:6, 20 parts by mass of C.I. Pigment Yellow 139, 80 parts by mass of SOLSPERSE 76500 (concentration of solid contents: 50 mass %; manufactured by Lubrication Technology Inc., concentration of solid contents: 50 mass %), and 700 parts by mass of propylene glycol monomethyl ether acetate were mixed with each other, and the obtained mixture was dispersed using a paint shaker for 8 hours. As a result, a dispersion 2 was obtained.

<Evaluation of Storage Stability>

Immediately after the preparation, each of the compositions was applied to a glass substrate such that the thickness of the formed film was 1.0 μm with a spin coating method using Act8 (manufactured by Tokyo Electron Ltd.), and the entire surface thereof was exposed using an i-ray stepper exposure device FPA-3000 i5+(manufactured by Canon Corporation) at an exposure dose of 1000 mJ/cm². Next, the coating film was heated using a hot plate at 220° C. for 5 minutes to form a cured film. The light transmittance of the obtained cured film in a wavelength range of 400 to 1,300 nm was measured using an ultraviolet-visible-near infrared spectrophotometer U-4100 (manufactured by Hitachi High-Technologies Corporation). Spectral characteristics of the cured film formed using the curable composition immediately after the preparation were set as spectral characteristics 1.

Next, immediately after the preparation, each of the curable compositions was stored in a clean room at a temperature of 23° C. for 2 months. Next, a cured film was manufactured as described above using each of the curable compositions after storage, and a light transmittance in a wavelength range of 400 to 1,300 nm was measured. Spectral characteristics of the cured film formed using the curable composition after the storage were set as spectral characteristics 2.

Using the spectral characteristics 1 and the spectral characteristics 2, a difference in transmittance at each wavelength between the cured film formed using the curable composition immediately after the preparation and the cured film formed using the curable composition after the storage was calculated, and a maximum value (ΔT %) of the difference in transmittance in a wavelength range of 400 to 1,300 nm was obtained to evaluate the storage stability based on the following standards.

5: ΔT %<1%

4: 1%≤ΔT %<2%

3: 2%≤ΔT %<3%

2: 3%≤ΔT %<5%

1: 5≤ΔT %

TABLE 5

| | Ex- | Ex- | Ex- | Ex- | Ex- | Ex- | Ex- | Ex- |
|---|---|---|---|---|---|---|---|---|
| | am- | am- | am- | am- | am- | am- | am- | am- |
| | ple | ple | ple | ple | ple | ple | ple | ple |
| | 1 | 2 | 3 | 4 | 5 | 6 | 7 | 8 |
| Stability | 5 | 5 | 5 | 5 | 3 | 3 | 5 | 4 |
| Over | | | | | | | | |
| Time | | | | | | | | |

TABLE 6

| | Ex- | Ex- | Ex- | Ex- | Ex- | Ex- | Ex- | Ex- |
|---|---|---|---|---|---|---|---|---|
| | am- | am- | am- | am- | am- | am- | am- | am- |
| | ple | ple | ple | ple | ple | ple | ple | ple |
| | 9 | 10 | 11 | 12 | 13 | 14 | 15 | 16 |
| Stability | 4 | 3 | 3 | 3 | 3 | 5 | 4 | 4 |
| Over | | | | | | | | |
| Time | | | | | | | | |

TABLE 7

| | Ex- | Ex- | Ex- | Ex- | Ex- | Ex- | Ex- | Ex- |
|---|---|---|---|---|---|---|---|---|
| | am- | am- | am- | am- | am- | am- | am- | am- |
| | ple | ple | ple | ple | ple | ple | ple | ple |
| | 17 | 18 | 19 | 20 | 21 | 22 | 23 | 24 |
| Stability | 3 | 3 | 5 | 5 | 5 | 5 | 5 | 5 |
| Over | | | | | | | | |
| Time | | | | | | | | |

TABLE 8

| | | | | | Com- | Com- | Com- | Com- | Com- |
|---|---|---|---|---|---|---|---|---|---|
| | | | | | par- | par- | par- | par- | par- |
| | | | | | ative | ative | ative | ative | ative |
| | Ex- | Ex- | Ex- | Ex- | Ex- | Ex- | Ex- | Ex- | Ex- |
| | am- | am- | am- | am- | am- | am- | am- | am- | am- |
| | ple | ple | ple | ple | ple | ple | ple | ple | ple |
| | 25 | 26 | 27 | 28 | 1 | 2 | 3 | 4 | 5 |
| Stability | 5 | 5 | 5 | 5 | 1 | 1 | 1 | 1 | 1 |
| Over | | | | | | | | | |
| Time | | | | | | | | | |

As shown in the tables, in all the Examples, a cured film having excellent stability over time and a suppressed variation in spectral characteristics before and after the storage of the curable composition was able to be formed.

### Test Example 2

The composition according to Example 5 was applied to a silicon wafer using a spin coating method such that the thickness of the formed film was 1.0 μm. Next, the coating film was heated using a hot plate at 100° C. for 2 minutes. Next, using an i-ray stepper exposure device FPA-3000 i5+(manufactured by Canon Corporation), the coating film was exposed through a mask of a 2 μm×2 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes. As a result, a 2 μm×2 μm Bayer pattern (near infrared cut filter) was formed.

Next, a Red composition was applied to the Bayer pattern of the near infrared cut filter using a spin coating method such that the thickness of the formed film was 1.0 μm. Next, the coating film was heated using a hot plate at 100° C. for 2 minutes. Next, using an i-ray stepper exposure device FPA-3000 i5+(manufactured by Canon Corporation), the coating film was exposed through a mask of a 2 μm×2 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes. As a result, the Red composition was patterned on the Bayer pattern of the near infrared cut filter. Likewise, a Green composition and a Blue composition were sequentially patterned to form red, green, and blue color patterns.

Next, the composition for forming an infrared transmitting filter was applied to the pattern-formed film using a spin coating method such that the thickness of the formed film was 2.0 μm. Next, the coating film was heated using a hot plate at 100° C. for 2 minutes. Next, using an i-ray stepper exposure device FPA-3000 i5+(manufactured by Canon Corporation), the coating film was exposed through a mask of a 2 μm×2 μm Bayer pattern at an exposure dose of 1000 mJ/cm². Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes. As a result, the infrared transmitting filter was patterned on a portion where the Bayer pattern of the near infrared cut filter was not formed. The obtained laminate was incorporated into a solid image pickup element using a well-known method. The obtained solid image pickup element was irradiated with light emitted from a 940 nm infrared light emitting diode (infrared LED) as a light source in a low-illuminance environment (0.001 Lux) to acquire images. Next, the imaging performance of the solid image pickup element was evaluated. The subject was able to be clearly recognized on the image. In addition, incidence angle dependence was good. In addition, this solid image pickup element had an infrared sensing function and a color recognition function.

The Red composition, the Green composition, the Blue composition, and the composition for forming an infrared transmitting filter used in Test Example 2 are as follows.

(Red Composition)

The following components were mixed and stirred, and the obtained mixture was filtered through a nylon filter (manufactured by Pall Corporation) having a pore size of 0.45 μm to prepare a Red composition.

| | | |
|---|---|---|
| Red Pigment Dispersion | 51.7 | parts by mass |
| Resin 14 (40 mass % PGMEA solution) | 0.6 | parts by mass |
| Polymerizable Compound 14 | 0.6 | parts by mass |
| Photopolymerization Initiator 101 | 0.3 | parts by mass |
| Surfactant 11 | 4.2 | parts by mass |
| PGMEA (propylene glycol monomethyl ether | 42.6 | parts by mass |
| acetate) | | |

(Green Composition)

The following components were mixed and stirred, and the obtained mixture was filtered through a nylon filter (manufactured by Pall Corporation) having a pore size of 0.45 μm to prepare a Green composition.

| | | |
|---|---|---|
| Green Pigment Dispersion | 73.7 | parts by mass |
| Resin 14 (40 mass % PGMEA solution) | 0.3 | parts by mass |
| Polymerizable Compound 11 | 1.2 | parts by mass |
| Photopolymerization Initiator 101 | 0.6 | parts by mass |
| Surfactant 11 | 4.2 | parts by mass |
| Ultraviolet absorber (UV-503, manufactured | 0.5 | parts by mass |
| by Daito Chemical Co., Ltd.) | | |
| PGMEA | 19.5 | parts by mass |

(Blue Composition)

The following components were mixed and stirred, and the obtained mixture was filtered through a nylon filter (manufactured by Pall Corporation) having a pore size of 0.45 μm to prepare a Blue composition.

| | | |
|---|---|---|
| Blue Pigment Dispersion | 44.9 | parts by mass |
| Resin 14 (40 mass % PGMEA solution) | 2.1 | parts by mass |
| Polymerizable Compound 11 | 1.5 | parts by mass |
| Polymerizable Compound 14 | 0.7 | parts by mass |
| Photopolymerization Initiator 101 | 0.8 | parts by mass |
| Surfactant 11 | 4.2 | parts by mass |
| PGMEA | 45.8 | parts by mass |

(Composition for Forming Infrared Transmitting Filter)

The following components were mixed and stirred, and the obtained mixture was filtered through a nylon filter (manufactured by Pall Corporation) having a pore size of 0.45 μm to prepare a composition for forming an infrared transmitting filter.

| | | |
|---|---|---|
| Pigment Dispersion 100 | 95.04 | parts by mass |
| Polymerizable Compound 16 | 1.84 | parts by mass |
| Resin 14 (40 mass % PGMEA solution) | 1.02 | parts by mass |
| Photopolymerization Initiator 1 | 0.883 | parts by mass |
| Surfactant 11 | 0.04 | parts by mass |
| Polymerization inhibitor (p-methoxyphenol) | 0.001 | parts by mass |
| PGMEA | 1.18 | parts by mass |

Raw materials used in the Red composition, the Green composition, the Blue composition, and the composition for forming an infrared transmitting filter are as follows.

Red Pigment Dispersion

9.6 parts by mass of C.I. Pigment Red 254, 4.3 parts by mass of C.I. Pigment Yellow 139, 6.8 parts by mass of a dispersant (Disperbyk-161, manufactured by BYK Chemie), and 79.3 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Red pigment dispersion was obtained.

Green Pigment Dispersion

6.4 parts by mass of C.I. Pigment Green 36, 5.3 parts by mass of C.I. Pigment Yellow 150, 5.2 parts by mass of a dispersant (Disperbyk-161, manufactured by BYK Chemie), and 83.1 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Green pigment dispersion was obtained.

Blue Pigment Dispersion

9.7 parts by mass of C.I. Pigment Blue 15:6, 2.4 parts by mass of C.I. Pigment Violet 23, 5.5 parts by mass of a dispersant (Disperbyk-161, manufactured by BYK Chemie), 82.4 parts by mass of PGMEA were mixed with each other to obtain a mixed solution, and the mixed solution was mixed and dispersed using a beads mill (zirconia beads; diameter: 0.3 mm) for 3 hours. As a result, a pigment dispersion was prepared. Next, using a high-pressure disperser NANO-3000-10 (manufactured by Nippon BEE Chemical Co., Ltd.) equipped with a pressure reducing mechanism, the pigment dispersion was further dispersed under a pressure of 2000 kg/cm³ at a flow rate of 500 g/min. This dispersing treatment was repeated 10 times. As a result, a Blue pigment dispersion was obtained.

Pigment Dispersion 100

A mixed solution having the following composition was mixed and dispersed using a beads mill (a high-pressure disperser with a pressure reducing mechanism, NANO-3000-10 (manufactured by Nippon BEE Chemical Co., Ltd.)), with zirconia beads having a diameter of 0.3 mm, until an average particle size (secondary particles) of a pyrrolopyrrole pigment was 75 nm or less. As a result, a pigment dispersion was prepared. The volume average particle size of a pigment in the pigment dispersion was measured using MICROTRAC UPA 150 (manufactured by Nikkiso Co., Ltd.).

| | |
|---|---|
| Pyrrolopyrrole pigment (the following compound) | 2.1 parts by mass |
| 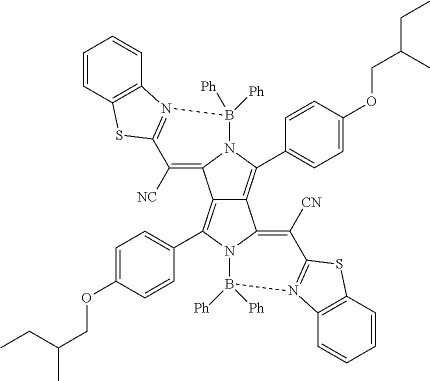 | |
| C.I. Pigment Red 254 | 2.1 parts by mass |
| C.I. Pigment Blue 15:6 | 2.1 parts by mass |
| Pigment derivative (the following compound) | 1.9 parts by mass |
| 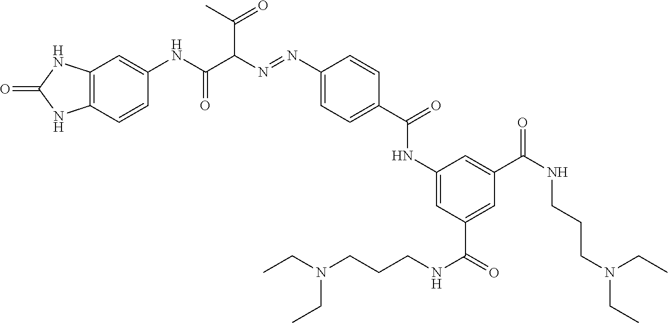 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1] | |
| Resin having the following structure (weight-average molecular weight: 8500, numerical values added to a main chain | 6.8 parts by mass |
| represent a molar ratio, a numerical value added to a side chain represents the number of repeating units) | |
| 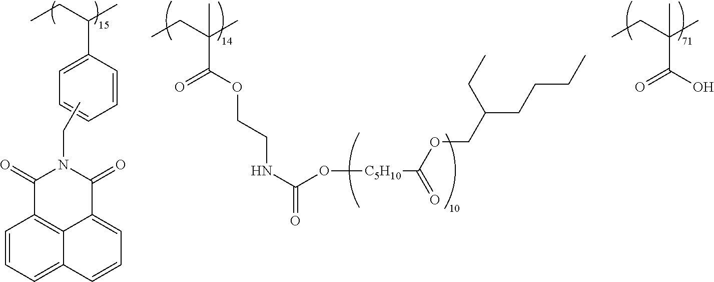 | |

Polymerizable compound 11: KAYARAD DPHA (manufactured by Nippon Kayaku Co., Ltd.)
Polymerizable compound 14: a compound having the following structure

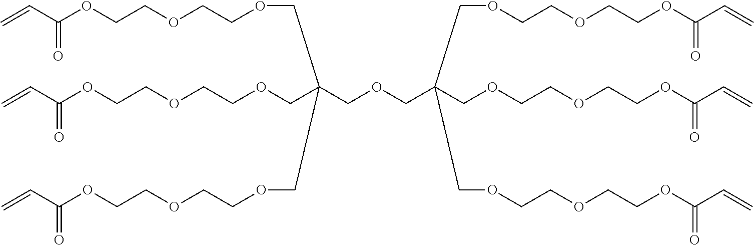 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable compound 16: M-305 (including 55 to 63 mass % of triacrylate; manufactured by Toagosei Co., Ltd.)

Resin 14: a resin having the following structure (acid value: 70 mgKOH/g, Mw=11000, a numerical value added to a main chain represents a mol number)

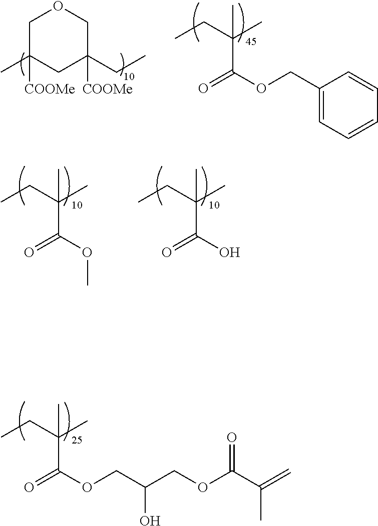

Photopolymerization Initiator 101: IRGACURE-379 (manufactured by BASF SE)
Surfactant 11: 1 mass % PGMEA solution of the following mixture (Mw: 14000; in the following formula, “%” representing the proportion of a repeating unit is mass %)

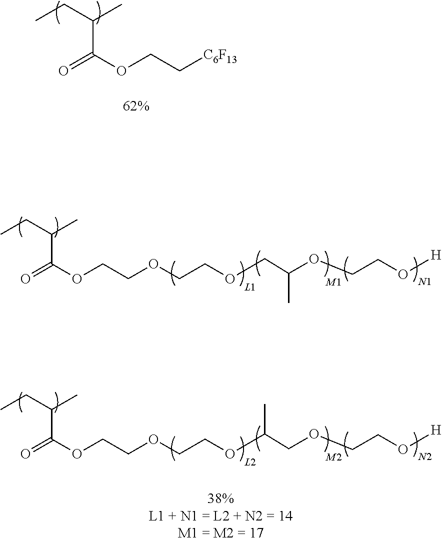

### EXPLANATION OF REFERENCES

110: solid image pickup element
111: near infrared cut filter
112: color filter
114: infrared transmitting filter
115: microlens
116: planarizing layer

What is claimed is:

1. A curable composition comprising:
a near infrared absorbing colorant;
a polymerizable compound; and
a photopolymerization initiator,
wherein the near infrared absorbing colorant is a compound that includes a π-conjugated plane having a monocyclic or fused aromatic ring,
a content of the near infrared absorbing colorant is 3 mass % or higher with respect to a total solid content of the curable composition, and
the photopolymerization initiator does not substantially include a compound having an oxime structure.

2. The curable composition according to claim 1,
wherein the photopolymerization initiator includes at least one selected from an alkylphenone compound, an acylphosphine oxide compound, a biimidazole compound, or a triazine compound.

3. The curable composition according to claim 2,
wherein the photopolymerization initiator includes at least one selected from an alkylphenone compound or an acylphosphine oxide compound.

4. The curable composition according to claim 1,
wherein the near infrared absorbing colorant includes at least one selected from a pyrrolopyrrole compound, a cyanine compound, or a squarylium compound.

5. The curable composition according to claim 1,
wherein the near infrared absorbing colorant includes at least two compounds having different maximum absorption wavelengths.

6. The curable composition according to claim 2,
wherein the near infrared absorbing colorant includes at least two compounds having different maximum absorption wavelengths.

7. The curable composition according to claim 4,
wherein the near infrared absorbing colorant includes at least two compounds having different maximum absorption wavelengths.

8. A cured film which is formed using the curable composition according to claim 1.

9. A near infrared cut filter comprising:
the cured film according to claim 8.

10. A solid image pickup element comprising:
the cured film according to claim 8.

11. An image display device comprising:
the cured film according to claim 8.

12. An infrared sensor comprising:
the cured film according to claim 8.
